(19) United States
(12) Patent Application Publication
(10) Pub. No.: US 2009/0283311 A1
(43) Pub. Date: Nov. 19, 2009

(54) Electronic element wafer module and method for manufacturing electronic element wafer module, electronic element module, and electronic information device

(75) Inventor: Tohru Ida, Osaka (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/387,433

(22) Filed: May 1, 2009

(30) Foreign Application Priority Data
May 14, 2008 (JP) 2008-127767

(51) Int. Cl. H05K 1/02; H05K 3/00

(52) U.S. Cl. 174/260; 29/846

(57) ABSTRACT

An electronic element wafer module is provided, and the module includes: electronic element wafers, in which a plurality of electronic elements are provided on the front surface side and wiring is provided on the back surface side; and support substrates adhered by a resin adhesive layer, opposing the front surface side of the electronic element wafer, where: a groove for dicing is formed along a dicing line in between adjacent electronic elements, penetrating the electronic element wafers from the back surface; and an insulation film for insulating a semiconductor layer from the wiring on the back surface is formed on the back surface of the electronic element wafer including the through hole and is formed at least on a side wall of the groove.

This nonprovisional application claims priority under 35 U.S.C. §119(a) to Patent Application No. 2008-127767 filed in Japan on May 14, 2008, the entire contents of which are hereby incorporated by reference.

### BACKGROUND OF THE INVENTION

1. Field of the Invention

The present invention relates to: an electronic element wafer module, in which a surface of an electronic element wafer, provided with a plurality of electronic elements, and a support substrate are laminated to each other; a method for manufacturing the electronic element wafer module; an electronic element module in which each individual piece is made by cutting off the electronic element wafer module for each electronic element; and an electronic information device, such as a digital camera (e.g., a digital video camera and a digital still camera), an image input camera, a scanner, a facsimile machine, and a camera-equipped cell phone device, having the electronic element module as an image input device used in an image capturing section thereof.

2. Description of the Related Art

In recent years, a demand is increasing for downsizing and thinning of electronic element modules, including the ones for camera modules (sensor modules) and the like, in which each individual piece is made by cutting off an electronic element wafer module having a plurality of substrates laminated therein (e.g., semiconductor substrate, glass substrate, and lens substrate). Thus, it is widely practiced to increase packaging density by laminating a plurality of substrates. Further, in an image sensor, in order to restrain a largeness of a package bottom area for wire bonding in a planar direction to achieve a real chip size package, what is watched with keen interest, is a technique of forming a through hole electrode that penetrates a semiconductor substrate (electronic element wafer) from an electrode pad formed on a chip surface of an electronic element module to connect a wiring to the back surface of the semiconductor substrate. This technique is discussed in References 1 and 2.

Reference 1 discloses a BGA (Ball Grid Array) type semiconductor apparatus having a through hole electrode and a method for manufacturing thereof. In Reference 1, a through hole electrode, which reaches from a back surface of a semiconductor substrate to a pad electrode formed on a front surface of the semiconductor substrate, and a wiring layer are formed, and subsequently, the semiconductor substrate and a support substrate are laminated to each other. Lastly, the semiconductor substrate and the support substrate are cut off for each electronic element (for each semiconductor apparatus) to separate them into a plurality of semiconductor chips.

Hereinafter, a method will be described specifically for making a plurality of semiconductor chips by dividing the semiconductor substrate after forming the through hole electrode with reference to FIG. 28.

FIG. 28 is a longitudinal cross sectional view of the vicinity of an electrode section and a dicing area of a semiconductor wafer module including the conventional through hole electrode, disclosed in Reference 1.

As illustrated in FIG. 28, an insulation film 102 is normally formed on a surface (lower surface) of a semiconductor substrate 101 (semiconductor wafer), and a metal wiring layer 103 is formed thereon. The metal wiring layer 103 includes an electrode pad formed therein for inputting and outputting signals of a semiconductor apparatus. The through hole electrode is formed in this electrode pad area. Further, an adhesive layer 104 is formed on the metal wiring layer 103, the adhesive layer 104 being formed of an oxide film, nitride film and the like as a protection film. Further, a support substrate 105 (e.g., glass substrate) is laminated on the adhesive layer 104 for reinforcing a semiconductor substrate 101.

In the semiconductor substrate 101, a through hole is formed right underneath an electrode pad, which is constituted of the metal wiring layer 103, and an insulation film 106 is formed in such a manner to cover the side and part of the bottom of the through hole and the back surface of the semiconductor substrate 101. A conductive layer 107 is formed between the electrode pad at the bottom of the through hole and the back surface of the semiconductor substrate 101, and the conductive layer 107 in the through hole functions as a through hole electrode 107a. In the back surface of the semiconductor substrate 101, the conductive layer 107 and the through hole electrode 107a are covered and protected by a protection film 108, and the location of the protection film 108 corresponding to an external connection terminal 109 is opened. With such a structure, the conductive layer 107 in the back surface of the semiconductor substrate 101 is electrically connected to the external connection terminal 109. As a result, there is an electrical connection between the electrode pad (metal wiring 103) existing on the front surface of the semiconductor substrate 101 and the external connection terminal 109 existing on the back surface, through the conductive layer 107. Lastly, the semiconductor substrate 101 and the support substrate 105 in the dicing line area are divided and individualized into the plurality of semiconductor chips.

On the other hand, a demand is increasing for further downsizing and thinning of small camera modules, representative of a cell phone device. For example, Reference 2 discloses a solid-state image capturing device in which a method for manufacturing a through hole electrode and a through hole electrode are applied.

According to Reference 2, a glass substrate is adhered as a support substrate on the front surface side of an electronic element wafer (semiconductor substrate, such as a silicon wafer), the electronic element wafer being provided with a plurality of solid-state image capturing elements each having an image capturing area formed at the center portion of the front surface and an electrode pad formed in the periphery portion thereof. Next, a via hole is formed from the back surface of the silicon wafer to reach the electrode pad, and simultaneously, a groove is formed, the groove being extended along the center of the dicing line and penetrating the silicon wafer from the back surface. Subsequently, a buffer layer, a wiring layer, a solder mask, and a solder ball are formed on the back surface of the silicon wafer by various processes including a process with a heat treatment. Lastly, the silicon wafer supported by the support substrate is divided, by dicing, into individual silicon chips, each of which includes a solid-state image capturing element.

As described above, the semiconductor apparatus including a through hole electrode, and a through hole electrode forming process are watched with ken interest in order to achieve the downsizing and thinning of wide variety of devices including a solid-state image capturing element as well as a memory. Both References 1 and 2 include a final process of dividing an electronic element wafer (semiconductor substrate) to make individual pieces for each electronic element.

FIG. 29 is a longitudinal cross sectional view of the vicinity of an electrode section and a dicing area of a semiconductor wafer module including the conventional through hole electrode, disclosed in Reference 2.

As illustrated in FIG. 29, when an electronic element wafer module is cutoff to manufacture an electronic element module, a groove 202 (=via hole) is formed along a dicing line area DL, simultaneously with the formation of a through hole 201 (=via hole). Subsequently, an insulation film 203 above the through hole 201 is also formed on the side wall of the groove 202.

Lastly, a plurality of individual electronic element modules are formed by the division along the dicing line area DL. In FIG. 29, a via hole 201, which extends from the back surface of the silicon wafer 204 as an electronic element wafer to the pad electrode 205, is formed and simultaneously, the groove 202, which extends along the dicing line center DS and penetrates the silicon wafer 204 from the back surface, is formed so that a resin adhesive layer 206 and a glass substrate 207 are cut to make individual electronic element modules.

Reference 1: Japanese Laid-Open Publication No. 2006-32699

Reference 2: Japanese Laid-Open Publication No. 2005-235859

### SUMMARY OF THE INVENTION

The conventional technique described above requires to lastly cut both the semiconductor substrate and the support substrate, or alternatively the support substrate, to make individual semiconductor apparatuses (electronic elements). This creates a problem where sections are exposed including the metal wiring of the support substrate and the semiconductor substrate. Due to the problem, it is extremely difficult to manufacture semiconductor chips that are reliable. To be specific, it is extremely difficult to manufacture semiconductor chips that include a through hole electrode with good moisture-resistance.

In Reference 1, it is necessary to cut off both the semiconductor substrate (semiconductor wafer) 101 and the support substrate 105 to individualize semiconductor apparatuses (electronic elements) having the through hole electrode 107a. For that, it is necessary to use a dicing blade for the semiconductor substrate 101 and another dicing blade for the support substrate 105 to cut them separately. For example, if the support substrate 105 is formed of a glass substrate, it is extremely difficult to cut both the semiconductor substrate 101 and the glass substrate (support substrate 105) with the same blade. Furthermore, a problem arises where the metal wiring layer 103 is exposed on the sections of the semiconductor substrate 101 and the support substrate 105, which makes the dicing troublesome and makes it difficult to achieve a semiconductor apparatus (electronic element module) with good moisture-resistance.

In Reference 2, a via hole 201, which extends from the back surface of the silicon wafer 204 as an electronic element wafer (semiconductor substrate) to the pad electrode 205, is formed and simultaneously, the groove 202, which extends along the dicing line center DS and penetrates the silicon wafer 204 from the back surface, is formed. Compared to the method according to Reference 1, electronic element modules can be individually divided by cutting off only the glass substrate 207, which is a support substrate, and therefore has the advantage of reducing the amount of work. However, similar to the method according to Reference 1 described above, a problem arises where sections of the silicon wafer 204 and the glass substrate 207, particularly the metal wiring layer 208 connected to the conductor in which the via hole 201 is buried, are exposed. Therefore, similar to the method according to Reference 1 described above, a problem arises where it is difficult to achieve an electronic element module having good moisture-resistance.

As described above, it is necessary to cut off both the semiconductor substrate and the support substrate, or alternatively the support substrate, in order to individualize semiconductor apparatuses having a through hole. Either way, the metal wiring layer is exposed on the adhered sections of the semiconductor substrate and the support substrate, with a risk of corrosion and leakage due to moisture on the surface.

The present invention is intended to solve the conventional problems described above. The objective of the present invention is to provide an electronic element wafer module, in which a through hole electrode has high moisture-resistance; a method for manufacturing the electronic element wafer module; an electronic element module in which each individual piece is individualized by cutting off the electronic element wafer module; and an electronic information device, such as a camera-equipped cell phone device, having the electronic element module as an image input device used in an image capturing section thereof.

An electronic element wafer module according to the present invention includes: electronic element wafers, in which a plurality of electronic elements are provided on a front surface side and wiring is provided on a back surface side, the wiring being electrically connected to wiring or a terminal section on the front surface side through a through hole penetrating through both surfaces; and support substrates adhered by a resin adhesive layer, opposing the front surface side of the electronic element wafer, wherein: a groove for dicing is formed along a dicing line in between adjacent electronic elements, penetrating the electronic element wafers from the back surface; and an insulation film for insulating a semiconductor layer from the wiring on the back surface is formed on the back surface of the electronic element wafer including the through hole and is formed at least on a side wall of the groove, thereby achieving the objective described above.

Preferably, in an electronic element wafer module according to the present invention, an electrode pad is provided as the wiring or terminal section in a periphery of the electronic element, and the electrode pad is connected to the wiring on the back surface through the through hole.

Still preferably, in an electronic element wafer module according to the present invention, the insulation film insulates an electric connection layer in the through hole and an inner wall of the through hole, the through hole being for electrically connecting the electrode pad provided in a periphery of the electronic element and the wiring or an external connection terminal.

Still preferably, in an electronic element wafer module according to the present invention, a back surface protection film is provided at least on the through hole on the back surface and the wiring.

Still preferably, in an electronic element wafer module according to the present invention, a bottom surface of the groove is either covered by the insulation film or removed.

Still preferably, in an electronic element wafer module according to the present invention, the bottom surface of the groove is located either on the support substrate or in the support substrate.

Still preferably, in an electronic element wafer module according to the present invention, the back surface protection film covers at least the side wall of the side wall and bottom surface of the groove.

Still preferably, in an electronic element wafer module according to the present invention, the back surface protection film is buried inside the groove.

Still preferably, in an electronic element wafer module according to the present invention, the support substrate is a transparent resin substrate or a transparent glass substrate as a transparent member.

Still preferably, in an electronic element wafer module according to the present invention, the insulation film is a photosensitive resin film, a Si oxide film, a boron or phosphor containing oxide film, Si oxynitride film, Si nitride film, or a laminated layer comprised of at least two types thereof, or a film formed with electrodeposition material.

Still preferably, in an electronic element wafer module according to the present invention, the photosensitive resin film is a polyimide resin, an epoxy resin or a acrylic resin.

Still preferably, in an electronic element wafer module according to the present invention, the electrodeposition material is a polyimide resin, an epoxy resin, a acrylic resin, a polyamine resin, or a polycarboxylic acid resin.

Still preferably, in an electronic element wafer module according to the present invention, an insulation film is further provided to insulate the wiring or terminal section from the semiconductor layer on the front surface of the electronic element wafer, and the insulation film is a Si oxide film, a boron or phosphor containing oxide film, Si oxynitride film, Si nitride film, or a laminated layer comprised of at least two types thereof.

Still preferably, in an electronic element wafer module according to the present invention, the back surface protection film is formed of a photosensitive resin film.

Still preferably, in an electronic element wafer module according to the present invention, the photosensitive resin film is a polyimide resin, an epoxy resin, a acrylic resin, a silicone resin, or a mixed resin comprised of at least two types thereof.

Still preferably, in an electronic element wafer module according to the present invention, the electronic element is an image capturing element including a plurality of light receiving sections for performing a photoelectric conversion on and capturing an image light from a subject.

Still preferably, in an electronic element wafer module according to the present invention, the electronic element includes a light emitting element for generating an output light and a light receiving element for receiving an incident light.

A method for manufacturing an electronic element wafer module according to the present invention includes: a step of laminating a support substrate opposing a front surface side of an electronic element wafer by a resin adhesive layer, the electronic element wafer having a plurality of electronic elements formed thereon; a through hole and groove forming step of forming a through hole, which penetrates through both surfaces of the electronic element wafer, for each electronic element and forming a groove for dicing, which penetrates the electronic element wafer from a back surface along a dicing line in between adjacent electronic elements; an insulation film forming step of forming an insulation film on the back surface of the electronic element wafer including the through hole and the groove; and a wiring layer forming step of forming a wiring layer on the insulation film, the wiring layer electrically connecting with wiring or a terminal section on the front surface side of the electronic element wafer through the through hole, thereby achieving the objective described above.

Preferably, a method for manufacturing an electronic element wafer module according to the present invention further includes a back surface protection film forming step of forming a back surface protection film on at least the wiring layer and the through hole.

Still preferably, a method for manufacturing an electronic element wafer module according to the present invention further includes an insulation film removing step of removing an insulation film on a bottom surface of the groove subsequent to the insulation film forming step.

Still preferably, in a method for manufacturing an electronic element wafer module according to the present invention, the through hole and groove forming step forms the groove such that a bottom surface of the groove is located on the support substrate or in the support substrate.

Still preferably, in a method for manufacturing an electronic element wafer module according to the present invention, the back surface protection film forming step buries the through hole with the back surface protection film and forms the back surface protection film on the groove or on an area other than the groove.

Still preferably, in a method for manufacturing an electronic element wafer module according to the present invention, the back surface protection film forming step forms the back surface protection film in such a manner to bury the through hole and the groove.

Still preferably, a method for manufacturing an electronic element wafer module according to the present invention further includes one or a plurality of laminated wafer-state optical apparatuses adhered and fixed on the transparent member in such a manner to correspond to each of the plurality of electronic elements.

Still preferably, in a method for manufacturing an electronic element wafer module according to the present invention, the one or a plurality of laminated wafer-state optical apparatuses are lens modules, and the electronic elements are image capturing elements.

Still preferably, in a method for manufacturing an electronic element wafer module according to the present invention, the one or a plurality of laminated wafer-state optical apparatuses are either prism modules or hologram element modules, and the electronic elements are light emitting elements and light receiving elements.

An electronic element module according to the present invention individually separated by cutting off every one or a predetermined number from the electronic element wafer module according to the present invention, thereby achieving the objective described above.

An electronic information device according to the present invention including the electronic element module, which is cut off from the electronic element wafer module according to the present invention, as a sensor module in an image capturing section, thereby achieving the objective described above.

An electronic information device according to the present invention including the electronic element module, which is cut off from the electronic element wafer module according to the present invention, in an information recording and reproducing section, thereby achieving the objective described above.

The functions and effects of the present invention having the structures described above will be described hereinafter.

In the present invention, walls on the side of a groove, which are divided by the groove of a dicing line area, are covered by an insulation film and/or a back surface protection film. As a result, an electronic element wafer, a glass substrate, which functions as a support substrate, and an adhesive resin layer thereof are not exposed directly to the outside. That is, such an electronic element wafer, a glass substrate, and an adhesive resin layer for laminating the semiconductor substrate and the glass substrate, are not exposed themselves, so that moisture from the outside will not enter through the adhesive resin layer into the electronic element wafer, causing the inside metal wiring to leak or causing the metal wiring to corrode. Further, with the structure described above, it becomes possible to cut off only the glass substrate to individualize electronic element modules, so that it is possible to simplify the process for individually dividing the electronic element wafer module.

In the present invention, the support substrate is laminated with the electronic element wafer functioning as a semiconductor substrate, so that the strength of the electronic element wafer can be increased. As a result, it becomes possible to provide a thin electronic element wafer. For example, when an electronic element wafer functioning as a semiconductor substrate is thinned by polishing and such, the strength of the electronic element wafer decreases as the polishing advances to some degree and then it becomes impossible to continue polishing the electronic element wafer further. However, by laminating the support substrate, the strength of the electronic element wafer increases and the further polishing becomes possible. As a result, it becomes possible to provide the thin electronic element wafer. The thin electronic element wafer has many advantages. For example, if the electronic element wafer is thick, the time for etching becomes long in forming a through hole in the electronic element wafer, which leads to the increase in the cost together with the difficulty in controlling the shape of the through hole. On the other hand, when the electronic element wafer is thinned, the above problems can be easily avoided.

It is necessary for a light to be effectively radiated onto a pixel area (image capturing area) through the support substrate. Therefore, when the electronic element of the present invention is configured as a CMOS solid-state image capturing element or a CCD solid-state image capturing element, the support substrate described above needs to reinforce the electronic element wafer while having a high transparency without disturbing the radiation of a light onto the pixel area.

As described above, the walls on the side of the groove, which are divided by the groove of a dicing line area, are covered by an insulation film and/or a back surface protection film. As a result, an electronic element wafer, a glass substrate, which functions as a support substrate, and an adhesive resin layer thereof are not exposed directly to the outside. That is, such an electronic element wafer, a glass substrate, and an adhesive resin layer for laminating the semiconductor substrate and the glass substrate, are not exposed themselves, so that moisture from the outside will not enter through the adhesive resin layer into the electronic element wafer, causing the inside metal wiring to leak or causing the metal wiring to corrode.

Further, with the structure described above, it becomes possible to cut off only the glass substrate to individualize electronic element modules, so that it is possible to simplify the process for individually dividing the electronic element wafer module. Because of these matters, it becomes possible to form the through hole electrode with high reliability, and in particular, with high moisture-resistance.

These and other advantages of the present invention will become apparent to those skilled in the art upon reading and understanding the following detailed description with reference to the accompanying figures.

### BRIEF DESCRIPTION OF THE DRAWINGS

FIG. 1 is an essential part longitudinal cross sectional view schematically illustrating a cross sectional structure of the vicinity of a through hole electrode and a dicing area of an electronic element wafer module according to Embodiment 1 of the present invention.

FIG. 2 is an essential part longitudinal cross sectional view schematically illustrating a cross sectional structure of the vicinity of an electrode section and a dicing area in each of the processes for manufacturing an electronic element wafer module according to Embodiment 1.

FIG. 3 is an essential part longitudinal cross sectional view schematically illustrating a cross sectional structure of the vicinity of a through hole electrode and a dicing area of an electronic element wafer module according to Embodiment 2 of the present invention.

FIG. 4 is an essential part longitudinal cross sectional view schematically illustrating a cross sectional structure of the vicinity of an electrode section and a dicing area in each of the processes for manufacturing an electronic element wafer module according to Embodiment 2.

FIG. 5 is an essential part longitudinal cross sectional view schematically illustrating a cross sectional structure of the vicinity of a through hole electrode and a dicing area of an electronic element wafer module according to Embodiment 3 of the present invention.

FIG. 6 is an essential part longitudinal cross sectional view schematically illustrating a cross sectional structure of the vicinity of an electrode section and a dicing area in each of the processes for manufacturing an electronic element wafer module according to Embodiment 3.

FIG. 7 is an essential part longitudinal cross sectional view schematically illustrating a cross sectional structure of the vicinity of a through hole electrode and a dicing area of an electronic element wafer module according to Embodiment 4 of the present invention.

FIG. 8 is an essential part longitudinal cross sectional view schematically illustrating a cross sectional structure of the vicinity of an electrode section and a dicing area in each of the processes for manufacturing an electronic element wafer module according to Embodiment 4.

FIG. 9 is an essential part longitudinal cross sectional view schematically illustrating a cross sectional structure of the vicinity of a through hole electrode and a dicing area of an electronic element wafer module according to Embodiment 5 of the present invention.

FIG. 10 is an essential part longitudinal cross sectional view schematically illustrating a cross sectional structure of the vicinity of an electrode section and a dicing area in each of the processes for manufacturing an electronic element wafer module according to Embodiment 5.

FIG. 11 is an essential part longitudinal cross sectional view schematically illustrating a cross sectional structure of the vicinity of a through hole electrode and a dicing area of an electronic element wafer module according to Embodiment 6 of the present invention.

FIG. 12 is an essential part longitudinal cross sectional view schematically illustrating a cross sectional structure of the vicinity of an electrode section and a dicing area in each of the processes for manufacturing an electronic element wafer module according to Embodiment 6.

FIG. 13 is an essential part longitudinal cross sectional view schematically illustrating a cross sectional structure of the vicinity of a through hole electrode and a dicing area of an electronic element wafer module according to Embodiment 7 of the present invention.

FIG. 14 is an essential part longitudinal cross sectional view schematically illustrating a cross sectional structure of the vicinity of an electrode section and a dicing area in each of the processes for manufacturing an electronic element wafer module according to Embodiment 7.

FIG. 15 is an essential part longitudinal cross sectional view schematically illustrating a cross sectional structure of the vicinity of a through hole electrode and a dicing area of an electronic element wafer module according to Embodiment 8 of the present invention.

FIG. 16 is an essential part longitudinal cross sectional view schematically illustrating a cross sectional structure of the vicinity of an electrode section and a dicing area in each of the processes for manufacturing an electronic element wafer module according to Embodiment 8.

FIG. 17 is an essential part longitudinal cross sectional view schematically illustrating a cross sectional structure of the vicinity of a through hole electrode and a dicing area of an electronic element wafer module according to Embodiment 9 of the present invention.

FIG. 18 is an essential part longitudinal cross sectional view schematically illustrating a cross sectional structure of the vicinity of an electrode section and a dicing area in each of the processes for manufacturing an electronic element wafer module according to Embodiment 9.

FIG. 19 is an essential part longitudinal cross sectional view schematically illustrating a cross sectional structure of the vicinity of a through hole electrode and a dicing area of an electronic element wafer module according to Embodiment 10 of the present invention.

FIG. 20 is an essential part longitudinal cross sectional view schematically illustrating a cross sectional structure of the vicinity of an electrode section a dicing area in each of the processes for manufacturing an electronic element wafer module according to Embodiment 10.

FIG. 21 is an essential part longitudinal cross sectional view schematically illustrating a cross sectional structure of the vicinity of a through hole electrode and a dicing area of an electronic element wafer module according to Embodiment 11 of the present invention.

FIG. 22 is an essential part longitudinal cross sectional view schematically illustrating a cross sectional structure of the vicinity of an electrode section and a dicing area in each of the processes for manufacturing an electronic element wafer module according to Embodiment 11.

FIG. 23 is an essential part longitudinal cross sectional view schematically illustrating a cross sectional structure of the vicinity of a through hole electrode and a dicing area of an electronic element wafer module according to Embodiment 12 of the present invention.

FIG. 24 is an essential part longitudinal cross sectional view schematically illustrating a cross sectional structure of the vicinity of an electrode section and a dicing area in each of the processes for manufacturing an electronic element wafer module according to Embodiment 12.

FIG. 25 is an essential part longitudinal cross sectional view schematically illustrating a cross sectional structure of the vicinity of an electrode section and a dicing area in the last process for manufacturing an electronic element wafer module according to Embodiment 12.

FIG. 26 is a longitudinal cross sectional view illustrating an exemplary essential structure of a sensor module according to Embodiment 13 of the present invention.

FIG. 27 is a block diagram illustrating an exemplary diagrammatic structure of an electronic information device of Embodiment 14 of the present invention, including the sensor module according to Embodiment 13 of the present invention used in an image capturing section.

FIG. 28 is a longitudinal cross sectional view of the vicinity of an electrode section and a dicing area of a semiconductor wafer module including the conventional through hole electrode, disclosed in Reference 1.

FIG. 29 is a longitudinal cross sectional view of the vicinity of an electrode section and a dicing area of a semiconductor wafer module including the conventional through hole electrode, disclosed in Reference 2.

1 electronic element wafer
2 support substrate (glass substrate)
3 adhesive resin layer
4 dicing area
5, 5A groove for dicing
6 electrode pad
7 through hole
8, 10 insulation film
9, 9A, 9B back surface protection film
12 metal wiring layer (electric connection wiring)
13 solder bump
20 to 32 electronic element wafer module
50 sensor module
51 through hole wafer
51a through hole
51b image capturing element (electronic element)
52 resin adhesive layer
53 glass plate
54, 541 to 543 lens plate
55, 56 lens adhesive layer
57 light shielding member
90 electronic information device
91 solid-state image capturing apparatus
92 memory section
93 display section
94 communication section
95 image output section

### DESCRIPTION OF THE PREFERRED EMBODIMENTS

Hereinafter, Embodiments 1 to 12 for an electronic element wafer module according to the present invention and a method for manufacturing the electronic element wafer module; Embodiment 13 for an electronic element module individually divided from the electronic element wafer module and further combined with a lens; and Embodiment 14 for an electronic information device, such as a camera-equipped cell phone device, having the electronic element module as an image input device used in an image capturing section thereof, will be described in detail with reference to the accompanying figures.

### Embodiment 1

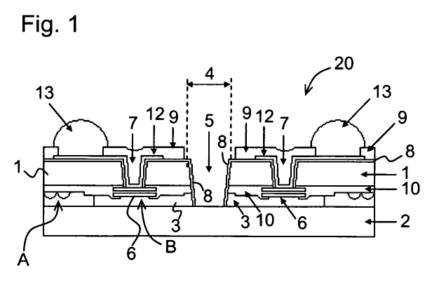

FIG. 1 is an essential part longitudinal cross sectional view schematically illustrating a cross sectional view of the vicinity of a through hole electrode and a dicing area of an electronic element wafer module according to Embodiment 1 of the present invention.

As illustrated in FIG. 1, an electronic element wafer module 20 according to Embodiment 1 includes: an electronic element wafer 1; and a glass substrate 2, functioning as a support substrate, the electronic element wafer 1 and glass substrate 2 being laminated to each other by an adhesive resin layer 3. A groove 5 is formed, which penetrates the electronic element wafer 1 from the back surface side along a dicing area 4 of the electronic element wafer 1 and reaches the glass substrate 2 functioning as the support substrate on the front surface side. The groove 5 is formed simultaneously with a through hole 7 for connecting with an electrode pad 6 (which can be a wiring section instead of a pad functioning as a terminal section), which functions as a wiring or a terminal section formed in a periphery section B of an electronic element area A at the center portion of each chip of the electronic element wafer 1. The side wall of the groove 5 is covered by an insulation film 8 on the back surface side of the electronic element wafer 1. The insulation film 8 is removed at the bottom surface of the groove 5. A protection film 9 on the back surface side of the electronic element wafer 1 is removed in a dicing area 4, and the protection film 9 is covered up to the edge section on the back surface along the dicing line edge. The surface of the glass substrate 2 is exposed on the bottom surface of the groove 5.

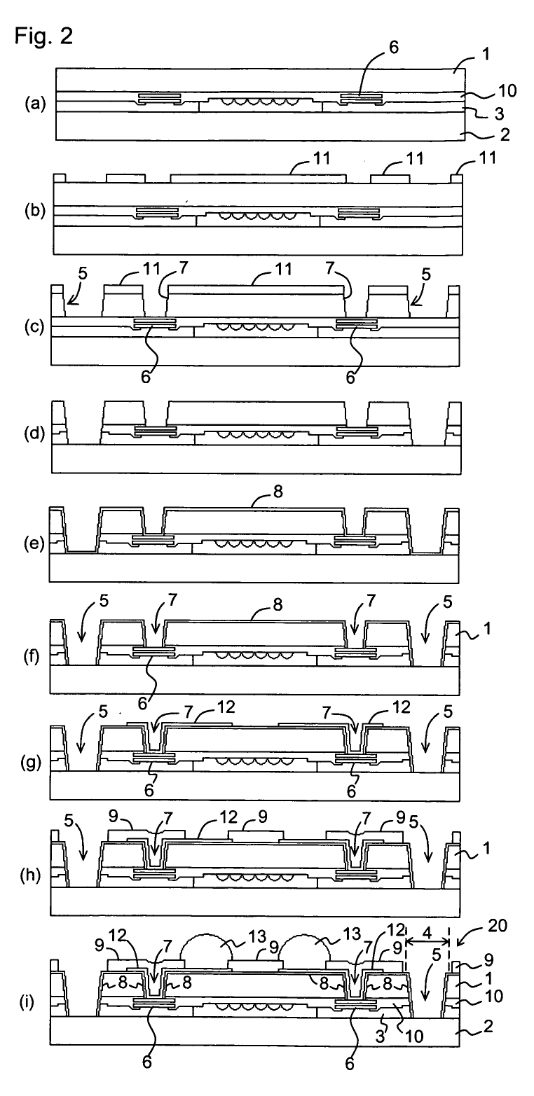

A method for manufacturing the electronic element wafer module 20 according to Embodiment 1 will be described in detail with reference to FIGS. 2(a) to 2(i).

FIGS. 2(a) to 2(i) are each an essential longitudinal cross sectional view schematically illustrating a cross sectional view of the vicinity of an electrode section and a dicing section in each process of manufacturing the electronic element wafer module 20 according to Embodiment 1.

Prior to reaching the cross sectional structure of FIG. 2(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 2(a), the glass substrate 2 is laminated as a support substrate on the surface of the electronic element wafer 1, using the adhesive resin layer 3.

Next, as illustrated in FIG. 2(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 for dicing in the latter processes.

The thickness of the electronic element wafer 1 described above is not specifically limited; however, it is preferable that the thickness be adjusted to the range of 50 μm to 300 μm by the polishing on the back surface. This is because, if the electronic element wafer 1 is too thick, the through hole 7 becomes too deep in when forming the through hole 7 in the electronic element wafer 1 in the later process, which results in the longer etching time to reduce the processing performance as well as the increase on the manufacturing cost and on the difficulty in the controlling of the shape of the through hole 7. Therefore, the depth of the etching is made shallow by thinning the thickness of the electronic element wafer 1 to some degree. Conversely, if the thickness of the electronic element wafer 1 is too thin, the handling in the later processes becomes difficult, as the risk of damaging increases and a curvature becomes easy to occur. Therefore, it is preferable that the thickness of the electronic element wafer 1 described above be set to the range of 50 μm to 300 μm.

As described with reference to FIG. 2(b), the resist film material is applied on the back surface (polished surface) of the electronic element wafer 1, and exposure and development are performed for the resist film 11 in such a manner to open the location corresponding to the electrode pad 6 on the front surface, so as to form a pattern as the resist film 11. The resist film 11 functions as a mask in the dry etching for forming the through hole 7 for the through hole electrode and the groove 5 for dicing in the electronic element wafer 1. The method for forming the resist film 11 described above is not specifically limited, but any publicly known method can be used as appropriate. Further, the material for the resist film 11 is not specifically limited, but any publicly known resist film can be used as appropriate.

Subsequently, as illustrated in FIG. 2(c), dry etching is performed on the electronic element wafer 1 using the resist film 11 as a mask to form the through hole 7 and the groove 5. The electronic element wafer 1 and the insulation film 10 directly below the electrode pad 6 are also etched by the dry etching, and the back surface of the electrode pad 6 is exposed. Subsequent to the etching, the resist film 11 described above is peeled and removed, as illustrated in FIG. 2(d).

Next, as illustrated in FIG. 2(e), the insulation film 8 is formed on the back surface of the electronic element wafer 1 in such a manner to cover the back surface of the electronic element wafer 1, the through hole 7, and the side walls and the bottom surface of the groove 5. It is desirable that the insulation film 8 be a plasma CVD film. Alternatively, it is preferable that the insulation film 8 be a polyimide, epoxy resin, or acrylic resin.

Further, as illustrated in FIG. 2(f), the insulation film 8 described above is etched using a reactive ion etching apparatus, and the insulation film 8 on the back surface of the electronic element wafer 1, through hole 7 and the side walls of the groove 5 is left to maintain the insulation for the metal wiring formed in the later process. The insulation film 8 on the bottom surface section of the through hole 7 is etched to be removed so that there will be an electrical connection between the metal wiring layer 12 and the electrode pad 6, which are formed in the later processes. In this case, the film thickness of the insulation film 8, which is formed on the back surface of the electronic element wafer 1, is sufficiently thicker compared to the thickness of the insulation film formed on the bottom surface of the through hole 7 and the bottom surface of the groove 5. Therefore, even if the insulation film 8 on each of the bottom surfaces of the through hole 7 and the groove 5 is removed by etching, the rest of the insulation film 8 on the back surface of the electronic element wafer 1 is sufficiently thick, so that the insulation is sufficiently maintained between the electronic element wafer 1 and the metal wiring layer 12.

An oxide film (insulation film 10) below the electrode pad 6 on the bottom surface of the through hole 7, and the insulation film 8 on the back surface are etched to be removed using fluoro carbon gas, such as C₄F₈, C₂F₆, CF₄ and CHF₃, so that there is an electrical connection between the electrode pad 6 on the front surface and the wiring layer 12 on the back surface.

Subsequently, although not shown in the figures, a barrier metal layer and a seed metal layer for electrolytic plating are formed on the back surface of the electronic element wafer 1. The method for forming the barrier metal layer and the seed metal layer is not specifically limited, but they can be formed by any publicly known method as appropriate. For example, they can be formed by a sputtering method or CVD method.

Next, as illustrated in FIG. 2(g), a metal wiring layer 12 (conductive wiring layer) is formed on the seed metal layer (not shown). The metal wiring layer 12 functions as a re-wiring pattern that electrically connects the back surface of the electrode pad 6 and an external connection terminal, which will be formed subsequently. The method for forming the metal wiring layer 12 is not specifically limited, but any publicly known method can be used as appropriate. For example, the metal wiring layer 12 can be formed by electrolytic copper plating and the like. With regard to the groove 5 for dicing, the electrode pad 6 is not formed, and therefore, there is no need to have an electrical connection and the metal wiring layer 12 is not formed here.

As a specific method for forming the metal wiring layer 12 described above, a resist film material is first applied on the back surface of the electronic element wafer 1 and the resist film material is exposed and developed by a common photolithography process so as to obtain a predetermined pattern of a resist film that corresponds to the re-wiring pattern. If it is difficult to apply a liquid form of the resist film material to the electronic element wafer 1 having the groove 5 for dicing provided therein, a film form of resist film material and the like can be used as the resist film material. Subsequently, the electrolytic copper plating is performed with the seed metal layer described above as the cathode, so that the thickness of the film of the re-wiring pattern, which corresponds to an opening portion of the resist film material described above, increases and the metal wiring layer 12 is formed. At this stage, the film thickness of the metal wiring layer 12 is not specifically limited. For example, it is preferable that the film thickness be 10 μm in order to mount a solder bump as an external input and output terminal in the later process. Subsequently, the resist film material is removed, and the unnecessary seed metal layer and barrier metal layer are removed by etching, as well. The process of forming the re-wiring pattern by the photolithography process and the process for performing the electrolytic copper plating can be performed in a reversed order. That is, an electrically conductive wiring layer is formed by electrolytic copper plating and the like on the seed metal layer formed on the entire back surface of the electronic element wafer 1. Next, the resist film material is exposed and developed by a common photolithography process such that the resist film material of the re-wiring pattern remains and the resist film material is removed other than the re-wiring pattern, so as to form the re-wiring pattern. Subsequently, the unnecessary copper plating layer, seed metal layer and barrier metal layer are removed by etching.

Subsequently, as illustrated in FIG. 2(h), the protection film 9 is formed with a photosensitive resin film on the entire back surface of the electronic element wafer 1. The photosensitive resin film described above is not specifically limited, but any publicly known photosensitive resin film can be used. In Embodiment 1, the protection film 9 is formed to fill the opening of the through hole 7. Next, openings are formed above the location where an external connection terminal to be described later and above the groove 5 for dicing in such a manner that the protection film 9 is not covered. The method for forming an opening of the protection film 9 is not specifically limited, but any publicly known method can be used as appropriate for the formation of the opening. For example, the opening can be formed by exposure and development in a photolithography process.

Next, as illustrated in FIG. 2(i), a solder bump 13, which will be an external input terminal, is formed at the opening area of the protection film 9 where the external connection terminal described above is located.

Subsequently, only the glass substrate 2 is diced along the groove 5 in the dicing area 4 by a dicing blade among the combination (electronic element wafer module) of the electronic element wafer 1 and the glass substrate 2, to be divided into individual semiconductor chips (electronic element modules). In Embodiment 1, since the side walls (adhesive resin layer 3 and insulation film 10, in particular) of the groove 5 of the dicing area 4 are covered by the insulation film 8 with regard to the individually separated semiconductor chips (electronic element modules), external moisture will not enter from the adhesive resin layer 3 into the electronic element wafer 1 to leak the internal metal wiring or corrode the metal wiring, thereby completing a semiconductor chip (electronic element module) with high reliability, and in particular, with high moisture-resistance.

### Embodiment 2

Hereinafter, an electronic element wafer module 21 according to Embodiment 2 will be described. Note that the structures which are not described in Embodiment 2 are the same as the ones in Embodiment 1. Additionally, for simplicity of the description, the members with the same function as the members illustrated in the figures of Embodiment 1 are added with the same reference numerals in Embodiment 2, but the description will be omitted.

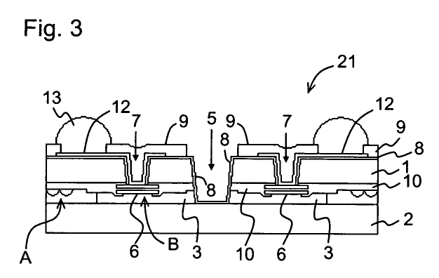

FIG. 3 is an essential part longitudinal cross sectional view schematically illustrating a cross sectional view of the vicinity of a through hole electrode and a dicing area of an electronic element wafer module according to Embodiment 2 of the present invention.

As illustrated in FIG. 3, an electronic element wafer module 21 according to Embodiment 2 includes: an electronic element wafer 1; and a glass substrate 2, functioning as a support substrate, the electronic element wafer 1 and glass substrate 2 being laminated to each other by an adhesive resin layer 3. A groove 5 is formed, which penetrates the electronic element wafer 1 from the back surface side along a dicing area 4 of the electronic element wafer 1 and reaches the glass substrate 2 functioning as the support substrate on the front surface side. The groove 5 is formed simultaneously with a through hole 7 for connecting with an electrode pad 6 formed in a periphery section B of an electronic element area A at the center portion of each chip of the electronic element wafer 1. The side wall of the groove 5 is covered by an insulation film 8 on the back surface side of the electronic element wafer 1. Although the insulation film 8 is removed from the bottom surface of the groove 5 in Embodiment 1, what is different from Embodiment 1 is that the insulation film 8 is not removed from the bottom surface of the groove 5 in order to have a good covering in Embodiment 2. The protection film 9 on the back surface side of the electronic element wafer 1 is removed in the dicing area 4, and the protection film 9 is covered up to the back surface edge section along the dicing line edge.

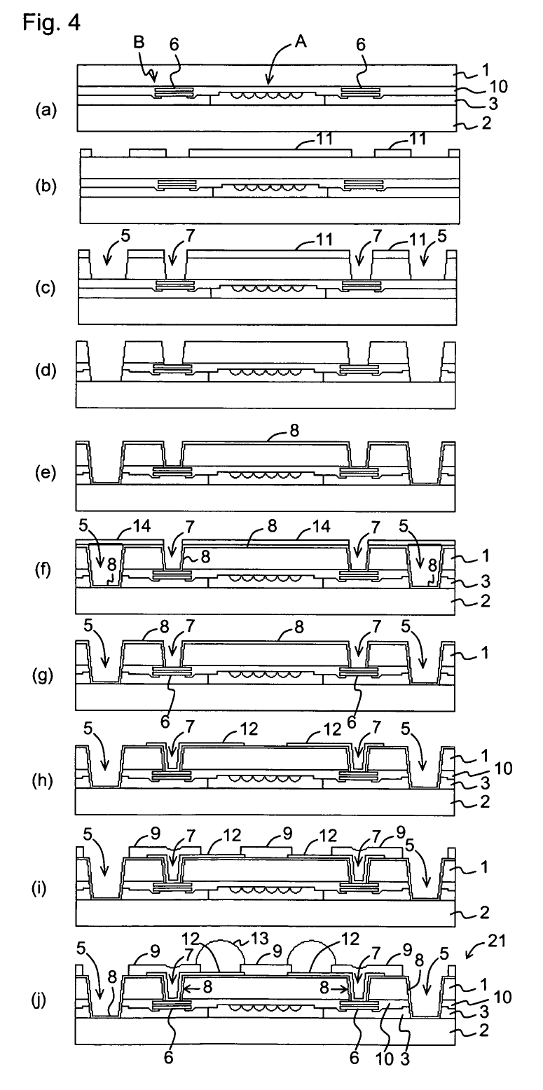

A method for manufacturing electronic element wafer module 21 according to Embodiment 2 will be described in detail with reference to FIGS. 4(a) to 4(j).

FIGS. 4(a) to 4(j) are each an essential part longitudinal cross sectional view schematically illustrating a cross sectional structure of the vicinity of an electrode section and an dicing area in each process for manufacturing the electronic element wafer module 21 according to Embodiment 2.

Prior to reaching the cross sectional structure of FIG. 4(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 4(a), the glass substrate 2 is laminated as a support substrate on the surface of the electronic element wafer 1, using an adhesive resin layer 3.

Next, as illustrated in FIG. 4(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

Hereinafter, the process in FIG. 4(c) through the process in FIG. 4(e) are the same as the processes as in Embodiment 1 described above (FIG. 2). Therefore, the descriptions with regard to these processes will be omitted.

As illustrated in FIG. 4(e), the insulation film 8 is formed on the back surface of the electronic element wafer 1 in such a manner to cover the back surface of the electronic element wafer 1, the through hole 7, and the side walls and the bottom surface of the groove 5. It is desirable that the insulation film 8 be a plasma CVD film. Alternatively, it is preferable that the insulation film 8 be a polyimide, epoxy resin, or acrylic resin.

Further, as illustrated in FIG. 4(f), the insulation film 8 is removed from the bottom surface of the through hole 7, and a resist film material is applied or laminated so as to be a resist film 14 for not removing the insulation film 8 on the bottom surface of the groove 5. Exposure and development are performed on the resist film material by a photolithography process to form a pattern in such a manner to have an opening of the resist film material for only the through hole 7. Subsequently, the insulation film 8 covering the bottom surface of the through hole 7 is etched to be removed using a reactive ion etching apparatus. Since the groove 5 for dicing is covered with the resist film 14, the insulation film 8 on the bottom surface of the groove 5 is not removed. At this stage, even if the insulation film 8 is etched to be removed from the bottom surfaces of the through hole 7, the insulation film 8 on the side surface of the through hole 7 is left, and therefore, the insulation is sufficiently maintained between the electronic element wafer 1 and the metal wiring layer 12.

Subsequently, although not shown in the figures, a barrier metal layer and a seed metal layer for electrolytic plating are formed on the back surface of the electronic element wafer 1 after the resist film 14 is removed. The method for forming the barrier metal layer and the seed metal layer is not specifically limited, but they can be formed by any publicly known method as appropriate. For example, they can be formed by a sputtering method or CVD method.

Hereinafter, FIG. 4(g) through FIG. 4(j) are the same as the cases in FIG. 2(f) through FIG. 2(i) Therefore, the description for each of the processes thereof will be omitted.

Subsequently, only the glass substrate 2 is diced along the groove 5 in the dicing area 4 by a dicing blade among the combination (electronic element wafer module) of the electronic element wafer 1 and the glass substrate 2, to be divided into individual semiconductor chips (electronic element modules). In Embodiment 2, the side walls and the bottom surface of the groove 5 of the dicing area 4 are covered by the insulation film 8 with regard to the individually separated semiconductor chips (electronic element modules), thereby completing a semiconductor chip (electronic element module) with high reliability, and in particular, with high moisture-resistance.

### Embodiment 3

Hereinafter, an electronic element wafer module 22 according to Embodiment 3 will be described. Note that the structures which are not described in Embodiment 3 are the same as the ones in Embodiment 1. Additionally, for simplicity of the description, the members with the same function as the members illustrated in the figures of Embodiment 1 are added with the same reference numerals in Embodiment 3, but the description will be omitted.

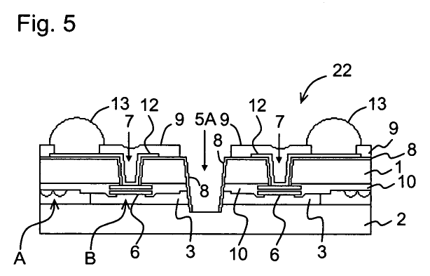

FIG. 5 is an essential part longitudinal cross sectional view schematically illustrating a cross sectional structure of the vicinity of a through hole electrode and an dicing area in an electronic element wafer module according to Embodiment 3 of the present invention.

As illustrated in FIG. 5, an electronic element wafer module 22 according to Embodiment 3 includes: an electronic element wafer 1; and a glass substrate 2, functioning as a support substrate, the electronic element wafer 1 and glass substrate 2 being laminated to each other by an adhesive resin layer 3. A groove 5A is formed, which penetrates the electronic element wafer 1 from the back surface side along the groove 5A of a dicing area 4 of the electronic element wafer 1 and reaches a front surface section of the glass substrate 2 functioning as the support substrate on the front surface side. The groove 5A is formed simultaneously with a through hole 7 for connecting with an electrode pad 6 formed in a periphery section B of an electronic element area A at the center portion of each chip of the electronic element wafer 1. The side wall of the groove 5A is covered by an insulation film 8 on the back surface side of the electronic element wafer 1. The insulation film 8 is removed from the bottom surface of the groove 5A (bottom surface of the groove of the glass substrate 2). The protection film 9 on the back surface side of the dicing area 4 is removed, and the protection film 9 is covered up to the back surface edge section along the dicing line edge. In short, in Embodiment 3, what is different from Embodiments 1 and 2 is that the groove 5A reaches the glass substrate 2 as a support substrate subsequent to penetrating the electronic element wafer 1, a shallow groove (concave portion) is formed in the glass substrate 2 by added etching, and the bottom surface of the groove 5A is located in the glass substrate 2 so as to have a good covering for the insulation film 8.

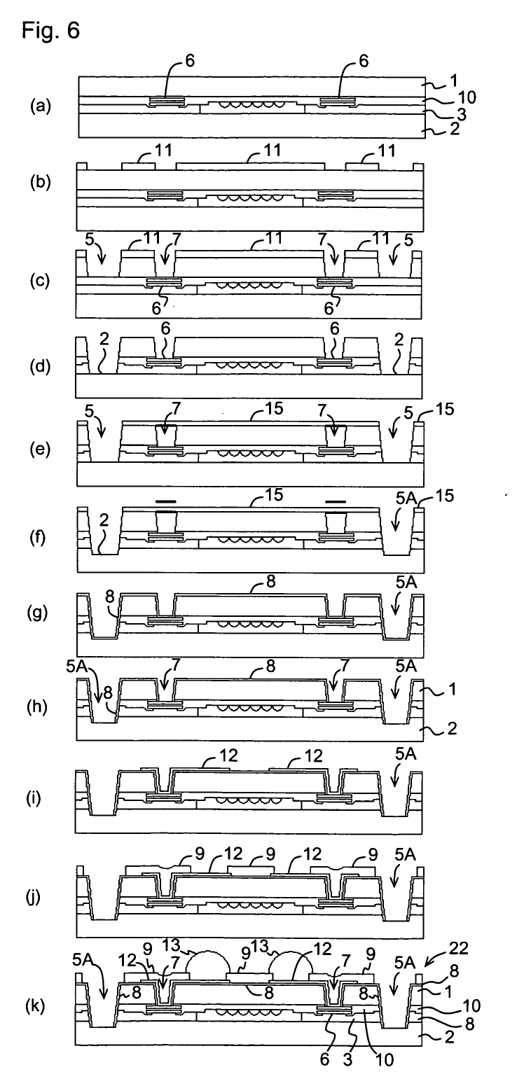

A method for manufacturing the electronic element wafer module 22 according to Embodiment 3 will be described in detail with reference to FIG. 6(a) to FIG. 6(k).

FIGS. 6(a) to 6(k) are each an essential part longitudinal cross sectional view schematically illustrating a cross sectional structure of the vicinity of an electrode section and a dicing area in each of the processes for manufacturing the electronic element wafer module 22 according to Embodiment 3.

Prior to reaching the cross sectional structure of FIG. 6(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 6(a), the glass substrate 2 is laminated as a support substrate on the surface of the electronic element wafer 1, using an adhesive resin layer 3.

Next, as illustrated in FIG. 6(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 for dicing in the latter processes.

Further, as illustrated in FIG. 6(c), dry etching is performed on the electronic element wafer 1 using the resist film 11 as a mask to form the through hole 7 and the groove 5.

Subsequently, as illustrated in FIG. 6(d), the bottom surface of the groove 5 and the insulation film 10 directly below the electrode pad 6 are also etched, so that the glass substrate 2 on the bottom surface of the groove 5 and the back surface of the electrode pad 6 are exposed.

Subsequently, as illustrated in FIG. 6(e), a resist film material is applied or laminated to cover the through hole 7 and the groove 5. Exposure and development are performed in the photolithography process for the resist film material described above to form a pattern of an opening for further etching the groove 5 in a depth direction, as a resist film 15.

Further, as illustrated in FIG. 6(f), etching is performed using a reactive ion etching apparatus with the resist film 15 as a mask, to dig a predetermined depth until the bottom surface of the groove 5 positions in the glass substrate 2. Since the through hole 7 is covered with the resist film 15, it is considered that the etching will not advance to the metal layer of the electrode pad 6. Herein, the glass substrate 2 is defined as a support substrate.

Further, as illustrated in FIG. 6(g), the insulation film 8 is formed to cover the back surface of the electronic element wafer 1, which is a semiconductor substrate, the through hole 7, and each of the side wall and the bottom surface of the groove 5A, subsequent to removing the resist film 15. It is desirable that the insulation film 8 be a plasma CVD film. Alternatively, it is preferable that the insulation film 8 be a polyimide, epoxy resin, or acrylic resin.

Further, as illustrated in FIG. 6(h), the insulation film 8 is etched using a reactive ion etching apparatus. In this case, the insulation films 8 on the back surface of the electronic element wafer 1, on the through hole 7, and on each sidewall of the groove 5 remain so that the electrical insulation can be maintained between a conductive wiring (metal wiring layer) to be formed in a later process and the electronic element wafer 1. The insulation film 8 on the bottom surface of the through hole 7 is etched to be removed so that there will be an electrical connection between the metal wiring layer 12 to be formed in the later process and the electrode pad 6. The film thickness of the insulation film 8 formed on the back surface of the electronic element wafer 1 is sufficiently thicker compared to the thickness of the insulation films formed respectively on the bottom surface of the through hole 7 and the bottom surface of the groove 5A for dicing. Therefore, even if the insulation film 8 on each of the bottom surfaces of the through hole 7 and the groove 5A is etched to be removed, the rest of the insulation film 8 on the back surface of the electronic element wafer 1 is sufficiently thick, so that the insulation is sufficiently maintained between the electronic element wafer 1 and the metal wiring layer 12.

Further, a barrier metal layer and a seed metal layer for electrolytic plating are formed on the back surface of the electronic element wafer 1. The method for forming the barrier metal layer and the seed metal layer is not specifically limited, but they can be formed by any publicly known method as appropriate. For example, they can be formed by a sputtering method or CVD method.

Hereinafter, the process in FIG. 6(i) through the process in FIG. 6(k) are the same as the cases in FIG. 2(g) through FIG. 2(i) in Embodiment 1. Therefore, the description for each of the processes thereof will be omitted.

Subsequently, the electronic element wafer module 22 is diced along the groove 5A for dicing to be individually separated into semiconductor chips (electronic element modules). In Embodiment 3, the side walls of the dicing line groove (groove 5A for dicing) are covered with the insulation film 8, and at the same time, the bottom surface of the groove 5A is located in the glass substrate 2 as a support substrate. Therefore, the interface between the glass substrate 2 and the adhesive resin layer 3 can also be covered by the insulation film 8, thereby completing an electronic element module (semiconductor apparatus) with better reliability, and in particular, with higher moisture-resistance, than the case in Embodiment 1 described above.

### Embodiment 4

Hereinafter, an electronic element wafer module 23 according to Embodiment 4 will be described. Note that the structures which are not described in Embodiment 4 are the same as the ones in Embodiment 1. Additionally, for simplicity of the description, the members with the same function as the members illustrated in the figures of Embodiment 1 are added with the same reference numerals in Embodiment 4, but the description will be omitted.

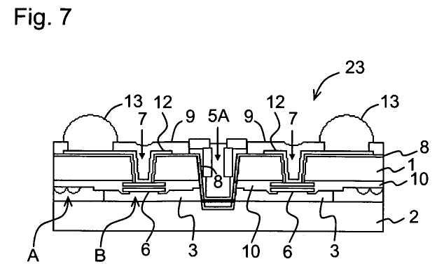

FIG. 7 is an essential part longitudinal cross sectional view schematically illustrating a cross sectional structure of the vicinity of a through hole electrode and a dicing area of an electronic element wafer module according to Embodiment 4 of the present invention.

As illustrated in FIG. 7, an electronic element wafer module 23 according to Embodiment 4 includes: an electronic element wafer 1; and a glass substrate 2, functioning as a support substrate, the electronic element wafer 1 and glass substrate 2 being laminated to each other by an adhesive resin layer 3. A groove 5A is formed, which penetrates the electronic element wafer 1 from the back surface side along the groove 5A of a dicing area 4 of the electronic element wafer 1 and reaches a front surface section of the glass substrate 2 functioning as the support substrate on the front surface side. The groove 5A is formed simultaneously with a through hole 7 for connecting with an electrode pad 6 formed in a periphery section B of an electronic element area A at the center portion of each chip of the electronic element wafer 1. The side wall of the groove 5A is covered by an insulation film 8 on the back surface side of the electronic element wafer 1. A bottom surface of the groove 5A (bottom surface of the groove of the glass substrate 2) is also covered by the insulation film 8. The protection film 9 on the back surface side of the dicing area 4 is removed, and the protection film 9 is covered up to the back surface edge section along the dicing line edge. In short, in Embodiment 4, what is different from Embodiments 1 to 3 is that the groove 5A reaches the glass substrate 2 as a support substrate subsequent to penetrating the electronic element wafer 1, further, a shallow groove is formed in the glass substrate 2 by added etching, the bottom surface of the groove 5A is located in the glass substrate 2, and the insulation film 8 is also formed on the bottom surface so as to have a good covering for the insulation film 8.

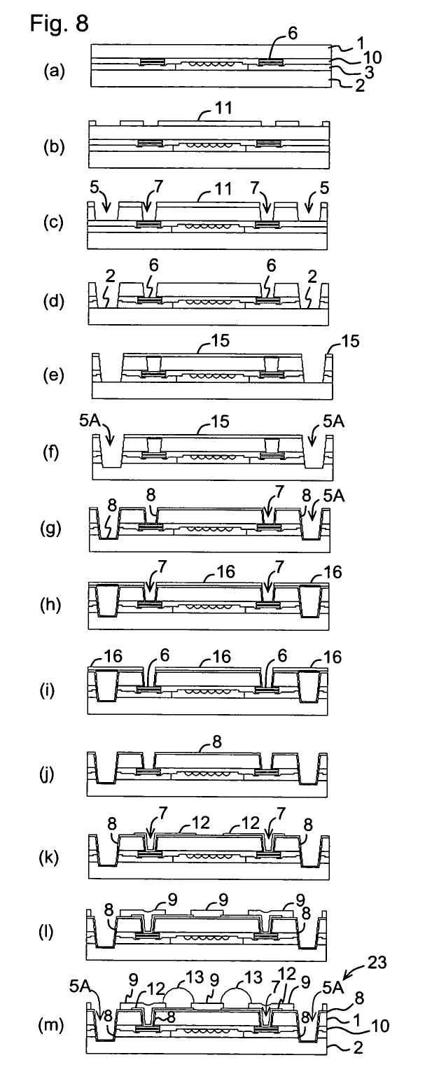

A method for manufacturing the electronic element wafer module 23 according to Embodiment 4 will be described in detail with reference to FIGS. 8(a) to 8(m).

FIGS. 8(a) to 8(m) each an essential part longitudinal cross sectional view schematically illustrating a cross sectional structure of the vicinity of an electrode section and a dicing area in each of the processes for manufacturing the electronic element wafer module 23 according to Embodiment 4.

Prior to reaching the cross sectional structure of FIG. 8(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 8(a), the glass substrate 2 is laminated as a support substrate on the surface of the electronic element wafer 1, using an adhesive resin layer 3.

Next, as illustrated in FIG. 8(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

Hereinafter, FIG. 8(c) through FIG. 8(g) are the same as the cases in FIG. 6(c) through FIG. 6(g) of Embodiment 3. Therefore, the description for each of the processes thereof will be omitted.

As illustrated in FIG. 8(h), a resist film material is applied or laminated to cover the through hole 7 and the groove 5A. Exposure and development are performed in the photolithography process for the resist film material described above to form a pattern of an opening for etching the insulation film 8 on the bottom surface of the through hole 7, as a resist film 16.

Further, as illustrated in FIG. 8(i), the insulation film 8 covering the bottom surface of the through hole 7 is etched to be removed using an a reactive ion etching apparatus. Since the groove 5A is covered by the resist film 16, the insulation film 8 at the bottom surface of the groove 5A is not removed. In this case, similar to the case of Embodiment 2 described above, even if the insulation film 8 on each of the bottom surfaces of the through hole 7 is removed by etching, the insulation film 8 on the side surface of the through hole 7 is left, and therefore, the insulation is sufficiently maintained between the electronic element wafer 1 and the metal wiring layer 12.

Further, a barrier metal layer and a seed metal layer for electrolytic plating are formed on the back surface of the electronic element wafer 1 subsequent to the removal of the resist film 16. The method for forming the barrier metal layer and the seed metal layer described above is not specifically limited, but they can be formed by any publicly known method as appropriate. For example, they can be formed by a sputtering method or CVD method.

Hereinafter, FIG. 8(k) through FIG. 8(m) are the same as the cases in FIG. 6(i) through FIG. 6(k) in Embodiment 3 described above. Therefore, the description for each of the processes thereof will be omitted.

Subsequently, the electronic element wafer module 23 is diced along the groove 5A for dicing to be individually separated into semiconductor chips (electronic element modules). In Embodiment 4, the side walls and bottom surface of the dicing line groove (groove 5A for dicing) are covered with the insulation film 8, and at the same time, the bottom surface of the groove 5A is located in the glass substrate 2 as a support substrate. Therefore, the covering by the insulation film 8 is better than the case of Embodiment 3 described above, thereby completing an electronic element module (semiconductor apparatus) with better reliability, and in particular, with higher moisture-resistance, than the case in Embodiment 3 described above.

### Embodiment 5

Hereinafter, an electronic element wafer module 24 according to Embodiment 5 will be described. Note that the structures which are not described in Embodiment 5 are the same as the ones in Embodiment 1. Additionally, for simplicity of the description, the members with the same function as the members illustrated in the figures of Embodiment 1 are added with the same reference numerals in Embodiment 5, but the description will be omitted.

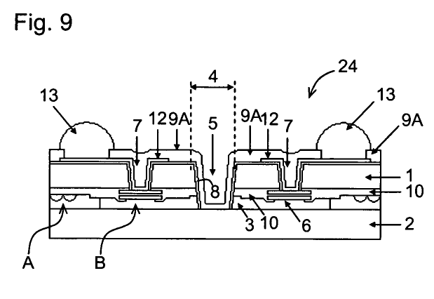

FIG. 9 is an essential part longitudinal cross sectional view schematically illustrating a cross sectional structure of the vicinity of a through hole electrode and a dicing area of an electronic element wafer module according to Embodiment 5 of the present invention.

As illustrated in FIG. 9, an electronic element wafer module 24 according to Embodiment 5 includes: an electronic element wafer 1; and a glass substrate 2, functioning as a support substrate, the electronic element wafer 1 and glass substrate 2 being laminated to each other by an adhesive resin layer 3. A groove 5 is formed, which penetrates the electronic element wafer 1 from the back surface side along the groove 5 of a dicing area 4 of the electronic element wafer 1 and reaches a front surface section of the glass substrate 2 functioning as the support substrate on the front surface side. The groove 5 is formed simultaneously with a through hole 7 for connecting with an electrode pad 6 formed in a periphery section B of an electronic element area A at the center portion of each chip of the electronic element wafer 1. The side wall of the groove 5 is covered by an insulation film 8 on the back surface side of the electronic element wafer 1. The insulation film 8 of the electronic element wafer 1 is removed from the bottom surface of the groove 5. A protection film 9A on the back surface of the dicing area 4 covers the side walls and bottom surface of the groove 5 and comes in contact with the surface of the glass substrate 2. In short, in Embodiment 5, what is different from Embodiment 1 is that the groove 5 penetrates the electronic element wafer 1, the bottom surface of the groove 5 is located on the surface of the glass substrate 2, and the side walls of the groove 5 is covered by the two layered structure of the insulation film 8 and the protection film 9A so as to have a good covering for the insulation film 8.

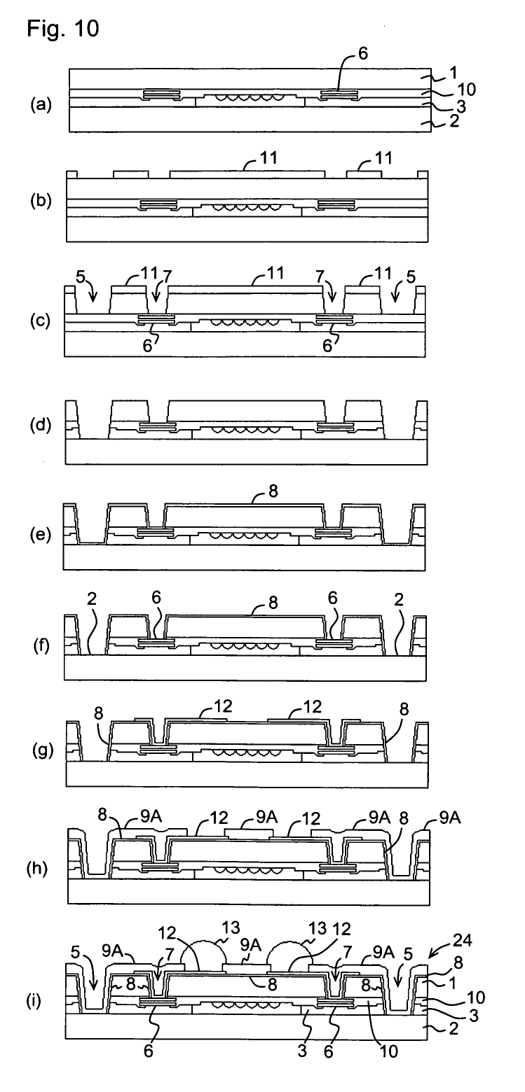

A method for manufacturing the electronic element wafer module 24 according to Embodiment 5 will be described in detail with reference to FIGS. 10(a) to 10(i).

FIGS. 10(a) to 10(i) are each an essential part longitudinal cross sectional view schematically illustrating a cross sectional structure of the vicinity of an electrode section and a dicing area in each of the processes for manufacturing the electronic element wafer module 24 according to Embodiment 5.

Prior to reaching the cross sectional structure of FIG. 10(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 10(a), the glass substrate 2 is laminated as a support substrate on the surface of the electronic element wafer 1, using an adhesive resin layer 3.

Next, as illustrated in FIG. 10(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

Hereinafter, FIG. 10(c) through FIG. 10(g) are the same as the cases in FIG. 2(c) through FIG. 2(g) of Embodiment 1. Therefore, the description for each of the processes thereof will be omitted.

As illustrated in FIG. 10(h), the protection film 9A is formed on the back surface side of the electronic element wafer 1. In forming the protection film 9A, since it is difficult to coat a resist on the side walls and bottom surface of the groove 5 of the dicing line with a common resist coater, what is called a spray coater is used. In FIG. 10(h), the protection film 9A of the dicing line area 4 is formed with a substantially equal resist thickness on the side walls and bottom surface of the groove 5, and the area of the through hole 7 is buried with the protection film 9A. There is no problem in forming the substantially equal thickness of the film on the side walls and bottom surface of the through hole 7 as the front surface.

Lastly, as illustrated in FIG. 10(i), a solder bump 13 is formed as an external connection electrode on the opening of the protection film 9A where the metal wiring layer 12 is exposed.

Subsequently, the electronic element wafer module 24 is diced along the groove 5 for dicing to be individually separated into semiconductor chips (electronic element modules). In Embodiment 5, the side walls of the dicing line groove (groove 5 for dicing) are covered with both the insulation film 8 and the protection film 9A. Therefore, the covering of the side walls of the groove 5 is better than the case of Embodiment 1 described above, thereby completing an electronic element module (semiconductor apparatus) with better reliability, and in particular, with higher moisture-resistance.

### Embodiment 6

Hereinafter, an electronic element wafer module 25 according to Embodiment 6 will be described. Note that the structures which are not described in Embodiment 6 are the same as the ones in Embodiment 1. Additionally, for simplicity of the description, the members with the same function as the members illustrated in the figures of Embodiment 1 are added with the same reference numerals in Embodiment 6, but the description will be omitted.

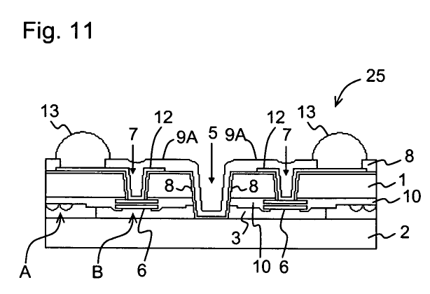

FIG. 11 is an essential part longitudinal cross sectional view schematically illustrating a cross sectional structure of the vicinity of a through hole electrode and a dicing area of an electronic element wafer module according to Embodiment 6 of the present invention.

As illustrated in FIG. 11, an electronic element wafer module 25 according to Embodiment 6 includes: an electronic element wafer 1; and a glass substrate 2, functioning as a support substrate, the electronic element wafer 1 and glass substrate 2 being laminated to each other by an adhesive resin layer 3. A groove 5 is formed, which penetrates the electronic element wafer 1 from the back surface side along a dicing area 4 of the electronic element wafer 1 and reaches the glass substrate 2 functioning as the support substrate on the front surface side. The groove 5 is formed simultaneously with a through hole 7 for connecting with an electrode pad 6 formed in a periphery section B of an electronic element area A at the center portion of each chip of the electronic element wafer 1. The side wall of the groove 5 is covered by an insulation film 8 on the back surface side of the electronic element wafer 1. Although the insulation film 8 is removed from the bottom surface of the groove 5 in Embodiments 1, 3 and 5 described above, the insulation film 8 is not removed from the bottom surface of the groove 5 in Embodiment 6, as similar to the case in Embodiments 2 and 4 described above. A protection film 9A on the back surface side of the dicing area 4 covers the side walls and bottom surface of the groove 5. In short, in Embodiment 6, what is different from Embodiments 2 and 5 is that the groove 5 penetrates the electronic element wafer 1, the bottom surface of the groove 5 is located on the surface of the glass substrate 2, and side walls and bottom surface of the groove 5 are both covered by the two layered structure of the insulation film 8 and the protection film 9A so as to have a better covering for side walls of the groove 5.

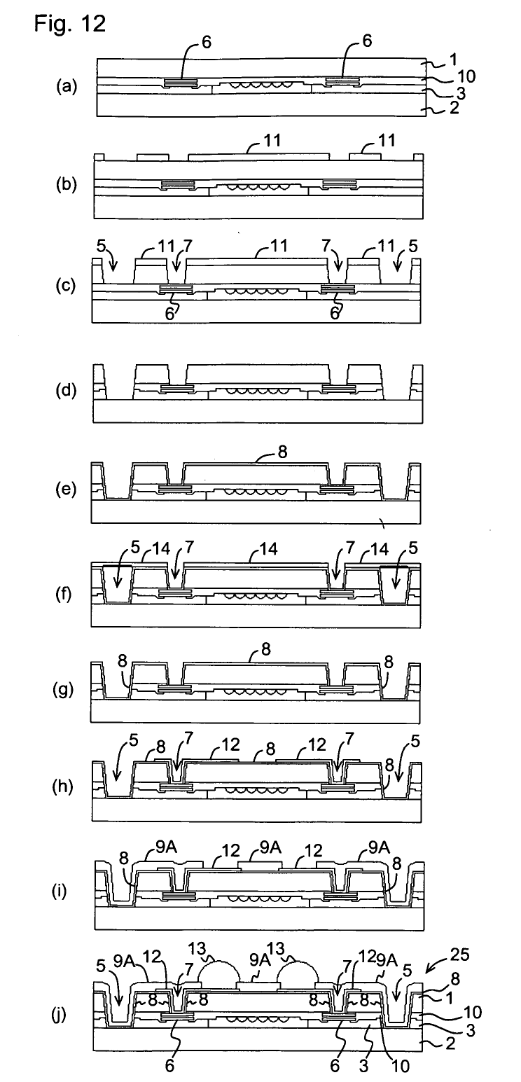

A method for manufacturing the electronic element wafer module 25 according to Embodiment 6 will be described in detail with reference to FIGS. 12(a) to 12(j).

FIGS. 12(a) to 12(j) are each an essential part longitudinal cross sectional view schematically illustrating a cross sectional structure of the vicinity of an electrode section and a dicing area in each of the processes for manufacturing the electronic element wafer module 25 according to Embodiment 6.

Prior to reaching the cross sectional structure of FIG. 12(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 12(a), the glass substrate 2 is laminated as a support substrate on the surface of the electronic element wafer 1, using an adhesive resin layer 3.

Next, as illustrated in FIG. 12(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

FIG. 12(c) through FIG. 12(h), which illustrate subsequent processes, are the same as the cases in FIG. 4(c) through FIG. 4(h) of Embodiment 2. Therefore, the description for each of the processes thereof will be omitted.

A barrier metal layer and a seed metal layer for electrolytic plating are formed on the back surface of the electronic element wafer 1, which is a semiconductor substrate, subsequent to the removal of the resist film 14. The method for forming the barrier metal layer and the seed metal layer described above is not specifically limited, but they can be formed by any publicly known method as appropriate. For example, they can be formed by a sputtering method or CVD method.

As illustrated in FIG. 12(i), the protection film 9A is formed on the back surface side of the electronic element wafer 1. In forming the protection film 9A, since it is difficult to coat a resist on the side walls and bottom surface of the groove 5 of the dicing line with a common resist coater, what is called a spray coater is used. In FIG. 12(i), the protection film 9A of the dicing line area 4 is formed with a substantially equal resist thickness on the side walls and bottom surface of the groove 5, and the area of the through hole 7 is buried with the protection film 9A. There is no problem in forming the substantially equal thickness of the protection film 9A on the side walls and bottom surface of the through hole 7 as the front surface.

Lastly, as illustrated in FIG. 12(j), a solder bump 13 is formed as an external connection electrode on the opening of the protection film 9A where the metal wiring layer 12 is exposed.

Subsequently, the electronic element wafer module 25 is diced along the groove 5 for dicing to be individually separated into semiconductor chips (electronic element modules). In Embodiment 6, the sidewalls and bottom surface of the dicing line groove (groove 5 for dicing) are covered with both the insulation film 8 and the protection film 9A. Therefore, the covering of the side walls of the groove 5 is better than the case of Embodiments 2 and 5 described above, thereby completing an electronic element module (semiconductor apparatus) with better reliability, and in particular, with higher moisture-resistance.

### Embodiment 7

Hereinafter, an electronic element wafer module 26 according to Embodiment 7 will be described. Note that the structures which are not described in Embodiment 7 are the same as the ones in Embodiment 1. Additionally, for simplicity of the description, the members with the same function as the members illustrated in the figures of Embodiment 1 are added with the same reference numerals in Embodiment 7, but the description will be omitted.

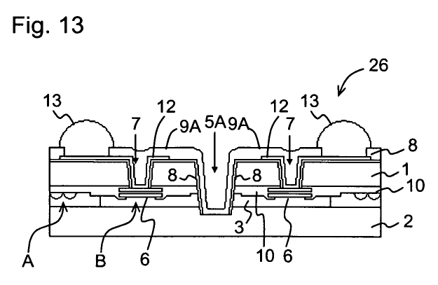

FIG. 13 is an essential part longitudinal cross sectional view schematically illustrating a cross sectional view of the vicinity of a through hole electrode and a dicing area of an electronic element wafer module according to Embodiment 7 of the present invention.

As illustrated in FIG. 13, an electronic element wafer module 26 according to Embodiment 7 includes: an electronic element wafer 1; and a glass substrate 2, functioning as a support substrate, the electronic element wafer 1 and glass substrate 2 being laminated to each other by an adhesive resin layer 3. A groove 5A is formed, which penetrates the electronic element wafer 1 from the back surface side along the groove 5A of a dicing area 4 of the electronic element wafer 1 and reaches a front surface section of the glass substrate 2 functioning as the support substrate on the front surface side. The groove 5A is formed simultaneously with a through hole 7 for connecting with an electrode pad 6 formed in a periphery section B of an electronic element area A at the center portion of each chip of the electronic element wafer 1. The side wall of the groove 5A is covered by an insulation film 8 on the back surface side of the electronic element wafer 1. The insulation film 8 is removed from the bottom surface of the groove 5A (bottom surface of a shallow groove of the glass substrate 2). A protection film 9A on the back surface side of the dicing area 4 covers the side walls and bottom surface of the groove 5A. In short, in Embodiment 7, what is different from Embodiment 3 is that the groove 5A penetrates the electronic element wafer 1, and subsequently, reaches the glass substrate 2 as a support substrate; further, a shallow groove (concave portion) is formed in the glass substrate 2 by added etching; and the bottom surface of the groove 5A is located in the glass substrate 2; and side walls of the groove 5 are covered by the two layered structure of the insulation film 8 and the protection film 9A so as to have a better covering for side walls of the groove 5A.

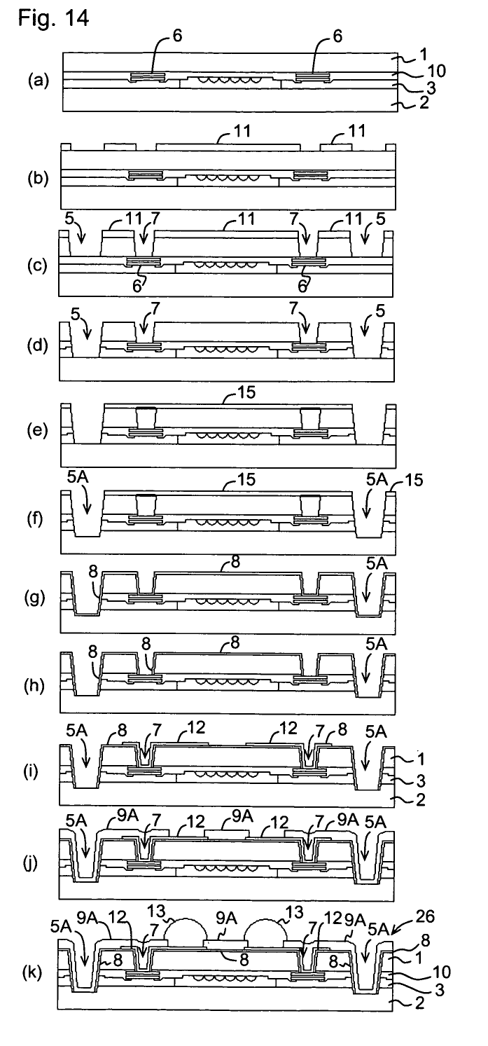

A method for manufacturing the electronic element wafer module 26 according to Embodiment 7 will be described in detail with reference to FIGS. 14(a) to 14(k).

FIGS. 14(a) to 14(k) are each an essential part longitudinal cross sectional view schematically illustrating a cross sectional structure of the vicinity of an electrode section and a dicing area in each of the processes for manufacturing the electronic element wafer module 26 according to Embodiment 7.

Prior to reaching the cross sectional structure of FIG. 14(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 14(a), the glass substrate 2 is laminated as a support substrate on the surface of the electronic element wafer 1, using an adhesive resin layer 3.

Next, as illustrated in FIG. 14(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

FIG. 14(c) through FIG. 14(i), which illustrate subsequent processes, are the same as the cases in FIG. 6(c) through FIG. 6(i) of Embodiment 3. Therefore, the description for each of the processes thereof will be omitted.

Subsequently, the electronic element wafer module 26 is diced along the groove 5A for dicing to be individually separated into semiconductor chips (electronic element modules). In Embodiment 7, the side walls of the dicing line groove (groove 5 for dicing) are covered with both the insulation film 8 and the protection film 9A, and the groove 5A for dicing is engraved into the glass substrate 2. Therefore, the covering of the side walls of the groove 5A is better than the case of Embodiment 3 described above, thereby completing an electronic element module (semiconductor apparatus) with better reliability, and in particular, with higher moisture-resistance. The protection film 9A of the dicing line area is formed with a substantially equal resist thickness on the side walls and bottom surface of the groove 5A, and the area of the through hole 7 is buried with the protection film 9A. There is no problem in forming the substantially equal thickness of the film on the side walls and bottom surface of the through hole 7 as the back surface side.

Lastly, as illustrated in FIG. 14(k), a solder bump 13 is formed as an external connection electrode on the opening of the protection film 9A where the metal wiring layer 12 is exposed.

Subsequently, the electronic element wafer module 26 is diced along the groove 5A for dicing to be individually separated into semiconductor chips (electronic element modules). In Embodiment 7, the side walls of the dicing line groove (groove 5A for dicing), which is engraved into the glass substrate 2, are covered with both the insulation film 8 and the protection film 9A. Therefore, the covering of the side walls of the groove 5A is better than the case of Embodiment 3 described above, thereby completing an electronic element module (semiconductor apparatus) with better reliability, and in particular, with higher moisture-resistance.

### Embodiment 8

Hereinafter, an electronic element wafer module 27 according to Embodiment 8 will be described. Note that the structures which are not described in Embodiment 8 are the same as the ones in Embodiment 1. Additionally, for simplicity of the description, the members with the same function as the members illustrated in the figures of Embodiment 1 are added with the same reference numerals in Embodiment 7, but the description will be omitted.

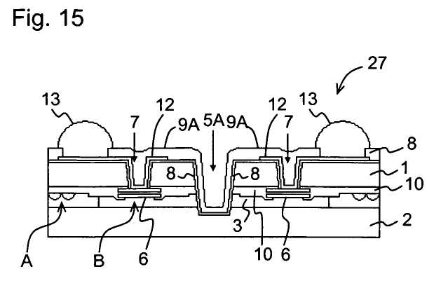

FIG. 15 is an essential part longitudinal cross sectional view schematically illustrating a cross sectional view of the vicinity of a through hole electrode and a dicing area of an electronic element wafer module according to Embodiment 8 of the present invention.

As illustrated in FIG. 15, an electronic element wafer module 27 according to Embodiment 8 includes: an electronic element wafer 1; and a glass substrate 2, functioning as a support substrate, the electronic element wafer 1 and glass substrate 2 being laminated to each other by an adhesive resin layer 3. A groove 5A is formed, which penetrates the electronic element wafer 1 from the back surface side along the groove 5A of a dicing area 4 of the electronic element wafer 1 and reaches a front surface section of the glass substrate 2 functioning as the support substrate on the front surface side. The groove 5A is formed simultaneously with a through hole 7 for connecting with an electrode pad 6 formed in a periphery section B of an electronic element area A at the center portion of each chip of the electronic element wafer 1. The side wall of the groove 5A is covered by an insulation film 8 on the back surface side of the electronic element wafer 1. The bottom surface of the groove 5A (bottom surface of the groove of the glass substrate 2) is also covered by the insulation film 8. A protection film 9A on the back surface side of the dicing area 4 covers the side walls and bottom surface of the groove 5A. In short, in Embodiment 8, what is different from Embodiment 4 is that the groove 5A penetrates the electronic element wafer 1, and subsequently, reaches the glass substrate 2 as a support substrate; further, a shallow groove (concave portion) is formed in the glass substrate 2 by added etching; and the bottom surface of the groove 5A is located in the glass substrate 2; and side walls of the groove 5A are covered by the two layered structure of the insulation film 8 and the protection film 9A so as to have a better covering for side walls of the groove 5A.

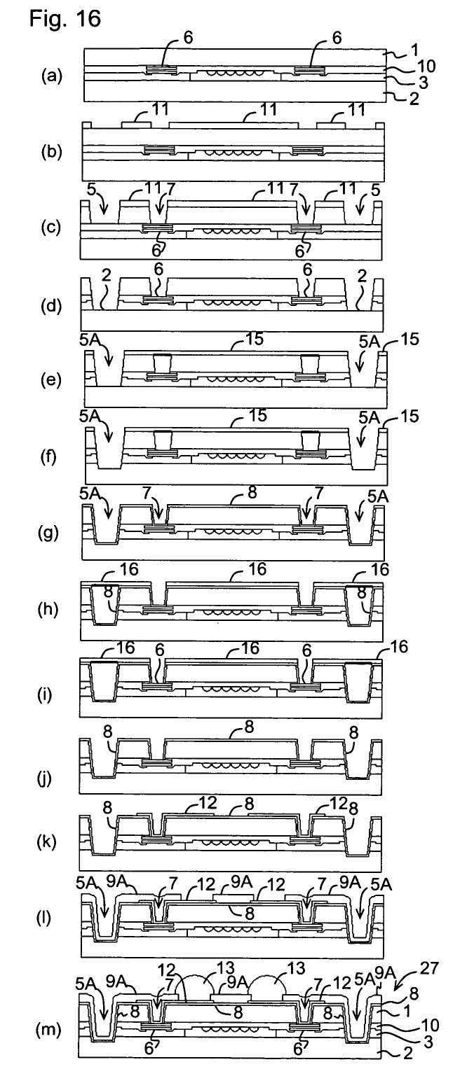

A method for manufacturing the electronic element wafer module 27 according to Embodiment 8 will be described in detail with reference to FIGS. 16(a) to 16(m).

FIGS. 16(a) to 16(m) are each an essential part longitudinal cross sectional view schematically illustrating a cross sectional structure of the vicinity of an electrode section and a dicing area in each of the processes for manufacturing the electronic element wafer module 27 according to Embodiment 8.

Prior to reaching the cross sectional structure of FIG. 16(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 16(a), the glass substrate 2 is laminated as a support substrate on the surface of the electronic element wafer 1, using an adhesive resin layer 3.

Next, as illustrated in FIG. 16(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

FIG. 16(c) through FIG. 16(k), which illustrate subsequent processes, are the same as the cases in FIG. 8(c) through FIG. 8(k) of Embodiment 4. Therefore, the description for each of the processes thereof will be omitted.

As illustrated in FIG. 16(l), the protection film 9A is formed on the back surface side of the electronic element wafer 1. In forming the protection film 9A, since it is difficult to coat a resist on the side walls and bottom surface of the groove 5A of the dicing line with a common resist coater, what is called a spray coater is used. In FIG. 16(l), the protection film 9A of the dicing line area 4 is formed with a substantially equal resist thickness on the side walls andbottom surface of the groove 5A, and the area of the through hole 7 is buried with the protection film 9A. There is no problem in forming the substantially equal thickness of the film on the side walls and bottom surface of the through hole 7 as the front surface.

Lastly, as illustrated in FIG. 16(m), a solder bump 13 is formed as an external connection electrode on the opening of the protection film 9A where the metal wiring layer 12 is exposed.

Subsequently, the electronic element wafer module 27 is diced along the groove 5A to be individually separated into semiconductor chips (electronic element modules). In Embodiment 8, the side walls and bottom surface of the dicing line groove (groove 5 for dicing) are covered with both the insulation film 8 and the protection film 9A. Further, the bottom surface of the groove 5A is located in the glass substrate 2 that is engraved from the surface of the glass substrate 2. Therefore, the covering of the side walls of the groove 5A is better than the case of Embodiment 4 described above, thereby completing an electronic element module (semiconductor apparatus) with better reliability, and in particular, with higher moisture-resistance.

### Embodiment 9

Hereinafter, an electronic element wafer module 28 according to Embodiment 9 will be described. Note that the structures which are not described in Embodiment 9 are the same as the ones in Embodiment 1. Additionally, for simplicity of the description, the members with the same function as the members illustrated in the figures of Embodiment 1 are added with the same reference numerals in Embodiment 9, but the description will be omitted.

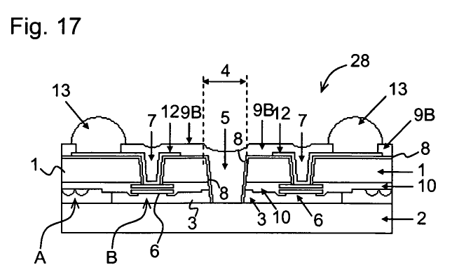

FIG. 17 is an essential part longitudinal cross sectional view schematically illustrating a cross sectional structure of the vicinity of a through hole electrode and a dicing area of an electronic element wafer module according to Embodiment 9 of the present invention.

As illustrated in FIG. 17, an electronic element wafer module 28 according to Embodiment 9 includes: an electronic element wafer 1; and a glass substrate 2, functioning as a support substrate, the electronic element wafer 1 and glass substrate 2 being laminated to each other by an adhesive resin layer 3. A groove 5 is formed, which penetrates the electronic element wafer 1 from the back surface side along a dicing area 4 of the electronic element wafer 1 and reaches the glass substrate 2 functioning as the support substrate on the front surface side. The groove 5 is formed simultaneously with a through hole 7 for connecting with an electrode pad 6 formed in a periphery section B of an electronic element area A at the center portion of each chip of the electronic element wafer 1. The side wall of the groove 5 is covered by an insulation film 8 on the back surface side of the electronic element wafer 1. The insulation film 8 is removed from the bottom surface of the groove 5. A protection film 9B in the dicing area 4 buries not only the through hole 7 but also the groove 5. This point is what is different from Embodiment 1 described above. The protection film 9B is in contact with the surface of the glass substrate 2 at the bottom of the groove 5.

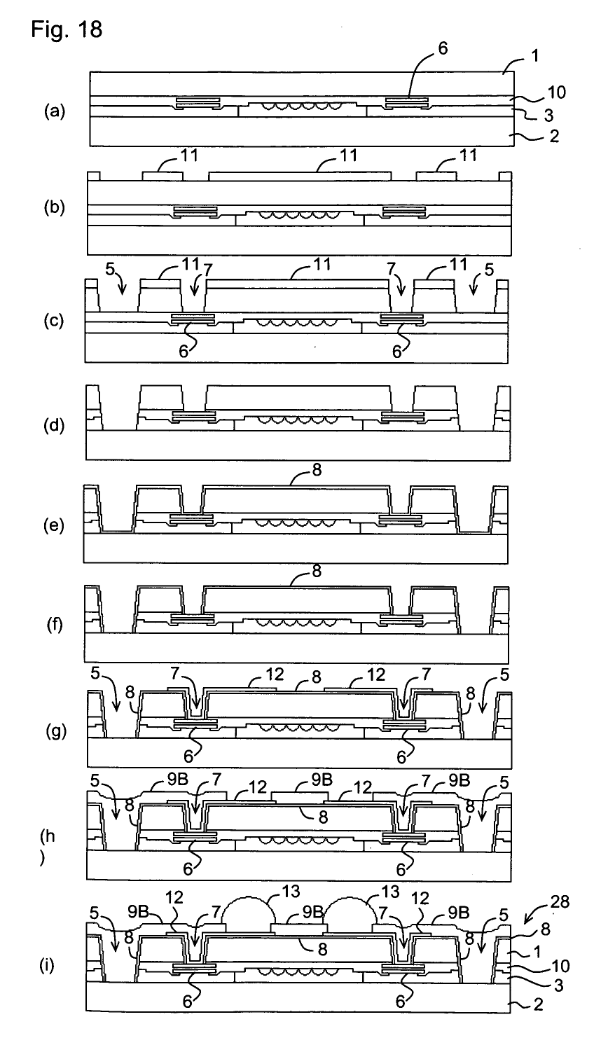

A method for manufacturing the electronic element wafer module 28 according to Embodiment 9 will be described in detail with reference to FIGS. 18(a) to 18(i).

FIGS. 18(a) to 18(i) are each an essential part longitudinal cross sectional view schematically illustrating a cross sectional structure of the vicinity of an electrode section and a dicing area in each of the processes for manufacturing the electronic element wafer module 28 according to Embodiment 9.

Prior to reaching the cross sectional structure of FIG. 18(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 18(a), the glass substrate 2 is laminated as a support substrate on the surface of the electronic element wafer 1, using an adhesive resin layer 3.

Next, as illustrated in FIG. 18(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

FIG. 18(c) through FIG. 18(g), which illustrate subsequent processes, are the same as the cases in FIG. 2(c) through FIG. 2(g) of Embodiment 1. Therefore, the description for each of the processes thereof will be omitted.

Further, as illustrated in FIG. 18(h), the protection film 9B is formed on the back surface side of the electronic element wafer 1 such that the protection film 9B is buried in the groove 5. The method for forming the protection film 9B is not specifically limited, but any publicly known method can be used as appropriate. For example, the burying of the protection film 9B is possible into the through hole 7 and the groove 5 for dicing, by application, deforming in a vacuum, vacuum laminator, or a printing method (vacuum).

Lastly, as illustrated in FIG. 18(i), a solder bump 13 is formed as an external connection electrode on the opening of the protection film 9B where the metal wiring layer 12 is exposed.

Subsequently, the electronic element wafer module 28 is diced along the groove 5 for dicing to be individually separated into semiconductor chips (electronic element modules). In Embodiment 9, the dicing line groove (groove 5 for dicing) is buried with the protection film 9B. Therefore, the package side wall surfaces (side wall surfaces of the groove 5 for dicing) subsequent to the individualization by dicing are covered by both the insulation film 8 and the thick protection film 9B. Similar to the case of Embodiment 5 described above, the covering of the insulation film 8 is excellent together with the addition of the thick protection film 9B, thereby completing an electronic element module (semiconductor apparatus) with high reliability, and in particular, with high moisture-resistance.

### Embodiment 10

Hereinafter, an electronic element wafer module 29 according to Embodiment 10 will be described. Note that the structures which are not described in Embodiment 10 are the same as the ones in Embodiment 1. Additionally, for simplicity of the description, the members with the same function as the members illustrated in the figures of Embodiment 1 are added with the same reference numerals in Embodiment 10, but the description will be omitted.

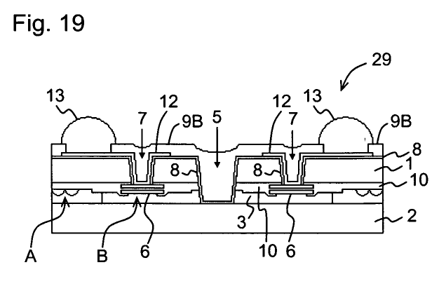

FIG. 19 is an essential part longitudinal cross sectional view schematically illustrating a cross sectional structure of the vicinity of a through hole electrode and a dicing area of an electronic element wafer module according to Embodiment 10 of the present invention.

As illustrated in FIG. 19, an electronic element wafer module 29 according to Embodiment 10 includes: an electronic element wafer 1; and a glass substrate 2, functioning as a support substrate, the electronic element wafer 1 and glass substrate 2 being laminated to each other by an adhesive resin layer 3. A groove 5 is formed, which penetrates the electronic element wafer 1 from the back surface side along a dicing area 4 of the electronic element wafer 1 and reaches the glass substrate 2 functioning as the support substrate on the front surface side. The groove 5 is formed simultaneously with a through hole 7 for connecting with an electrode pad 6 formed in a periphery section B of an electronic element area A at the center portion of each chip of the electronic element wafer 1. The side wall of the groove 5 is covered by an insulation film 8 on the back surface side of the electronic element wafer 1. Although the insulation film 8 is removed from the bottom surface of the groove 5 in Embodiment 9 described above, the insulation film 8 is not removed from the bottom surface of the groove 5 in Embodiment 10 so that the covering of the insulation film 8 is made to be favorable. A protection film 9B in the dicing area 4 buries not only the through hole 7 but also the groove 5. This point is what is different from Embodiment 2 described above.

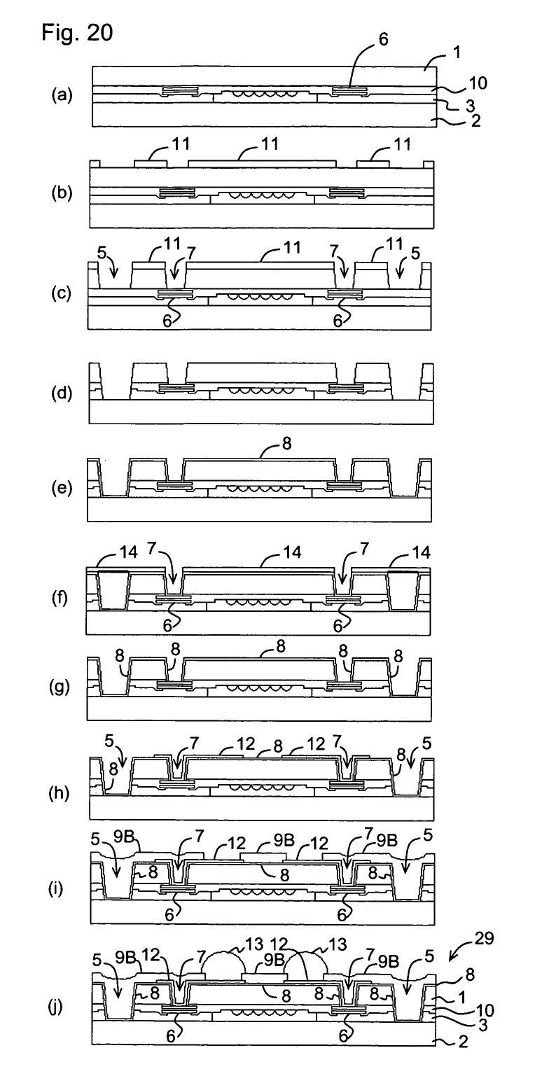

A method for manufacturing the electronic element wafer module 29 according to Embodiment 10 will be described in detail with reference to FIGS. 20(a) to 20(j).

FIGS. 20(a) to 20(j) are each an essential part longitudinal cross sectional view schematically illustrating a cross sectional structure of the vicinity of an electrode section and a dicing area in each of the processes for manufacturing the electronic element wafer module 29 according to Embodiment 10.

Prior to reaching the cross sectional structure of FIG. 20(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

First, as illustrated in FIG. 20(a), the glass substrate 2 is laminated as a support substrate on the surface of the electronic element wafer 1, using an adhesive resin layer 3.

Next, as illustrated in FIG. 20(b), a resist film material is applied or laminated, which will be a resist film 11 for forming the through hole 7 and the groove 5 for dicing. Exposure and development are performed by a photolithography process with respect to the resist film material, so that an opening is formed to be a pattern as the resist film 11 for forming the through hole 7 and the groove 5 in the latter processes.

FIG. 20(c) through FIG. 20(h), which illustrate subsequent processes, are the same as the cases in FIG. 4(c) through FIG. 4(h) of Embodiment 2 described above. Therefore, the description for each of the processes thereof will be omitted.

Further, as illustrated in FIG. 20(i), the protection film 9B is formed on the back surface side of the electronic element wafer 1 such that the protection film 9B is buried in the groove 5. The method for forming the protection film 9B is not specifically limited, but any publicly known method can be used as appropriate. For example, the burying of the protection film 9B is possible into the through hole 7 and the groove 5, by application, deforming in a vacuum, vacuum laminator, or a printing method (vacuum).

Lastly, as illustrated in FIG. 20(j), a solder bump 13 is formed as an external connection electrode on the opening of the protection film 9B where the metal wiring layer 12 is exposed.

Subsequently, the electronic element wafer module 29 is diced along the groove 5 for dicing to be individually separated into semiconductor chips (electronic element modules). In Embodiment 10, the protection film 9B is filmed and buried on the insulation film 8 in the dicing line groove (groove 5 for dicing). Therefore, the package side wall surfaces (side wall surfaces of the groove 5 for dicing) subsequent to the individualization by dicing are covered by both the insulation film 8 and the thick protection film 9B. Compared to the case of Embodiment 6 described above, the covering of the insulation film is better together with the addition of the thick protection film 9B, thereby completing an electronic element module (semiconductor apparatus) with high reliability, and in particular, with high moisture-resistance.

### Embodiment 11

Hereinafter, an electronic element wafer module 30 according to Embodiment 11 will be described. Note that the structures which are not described in Embodiment 11 are the same as the ones in Embodiment 1. Additionally, for simplicity of the description, the members with the same function as the members illustrated in the figures of Embodiment 1 are added with the same reference numerals in Embodiment 11, but the description will be omitted.

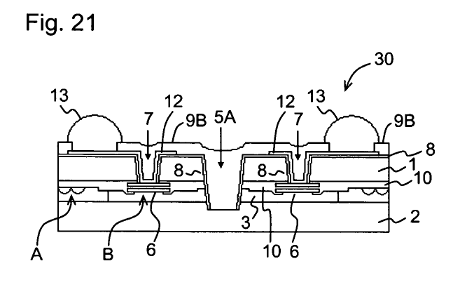

FIG. 21 is an essential part longitudinal cross sectional view schematically illustrating a cross sectional structure of the vicinity of a through hole electrode and a dicing area of an electronic element wafer module according to Embodiment 11 of the present invention.

As illustrated in FIG. 21, an electronic element wafer module 30 according to Embodiment 11 includes: an electronic element wafer 1; and a glass substrate 2, functioning as a support substrate, the electronic element wafer 1 and glass substrate 2 being laminated to each other by an adhesive resin layer 3. A groove 5A is formed, which penetrates the electronic element wafer 1 from the back surface side along a groove 5A of a dicing area 4 of the electronic element wafer 1 and reaches the front surface of the glass substrate 2 functioning as the support substrate on the front surface side. The groove 5A is formed simultaneously with a through hole 7 for connecting with an electrode pad 6 formed in a periphery section B of an electronic element area A at the center portion of each chip of the electronic element wafer 1. The side wall of the groove 5A is covered by an insulation film 8 on the back surface side of the electronic element wafer 1. The insulation film 8 is removed from the bottom surface of the groove 5A (bottom surface of the groove of the glass substrate 2). A protection film 9B in the dicing area 4 buries not only the through hole 7 but also the groove 5. This point is what is different from Embodiment 3 described above.

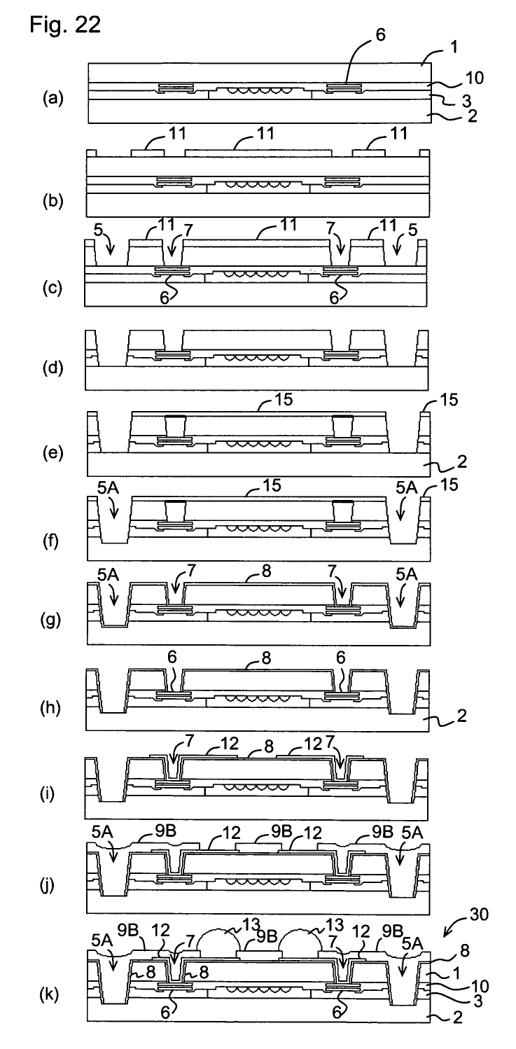

A method for manufacturing the electronic element wafer module 30 according to Embodiment 11 will be described in detail with reference to FIGS. 22(a) to 22(k).

FIGS. 22(a) to 22(k) are each an essential part longitudinal cross sectional view schematically illustrating a cross sectional structure of the vicinity of an electrode section and a dicing area in each of the processes for manufacturing the electronic element wafer module 30 according to Embodiment 11.

Prior to reaching the cross sectional structure of FIG. 22(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

FIG. 22(a) through FIG. 22(i), which illustrate subsequent processes, are the same as the cases in FIG. 6(a) through FIG. 6(i) of Embodiment 3 described above. Therefore, the description for each of the processes thereof will be omitted.

Next, as illustrated in FIG. 22(j), the protection film 9B is formed on the back surface side of the electronic element wafer 1. The method for forming the protection film 9B is not specifically limited, but any publicly known method can be used as appropriate. For example, the burying of the protection film 9B is possible into the through hole 7 and the dicing line groove 5A, by application, deforming in a vacuum, vacuum laminator, or a printing method (vacuum).

Lastly, as illustrated in FIG. 22(k), a solder bump 13 is formed thereon.

Subsequently, the electronic element wafer 1 is diced along the dicing line groove 5A for dicing to be individually separated into semiconductor chips. In Embodiment 11, the dicing line groove 5A is buried by the protection film 9B. Therefore, the side walls of the groove 5A, which constitute the package side wall surfaces subsequent to the individualization by dicing, are covered by both the insulation film 8 and the thick protection film 9B. Further, the bottom surface of the dicing line groove 5A is located in the glass substrate 2 as a support substrate. Therefore, compared to the case of Embodiment 9 described above, the covering of the insulation film 8 is better, thereby completing an electronic element module 30 with high reliability, and in particular, with high moisture-resistance.

### Embodiment 12

Hereinafter, an electronic element wafer module 31 according to Embodiment 12 will be described. Note that the structures which are not described in Embodiment 12 are the same as the ones in Embodiment 1. Additionally, for simplicity of the description, the members with the same function as the members illustrated in the figures of Embodiment 1 are added with the same reference numerals in Embodiment 12, but the description will be omitted.

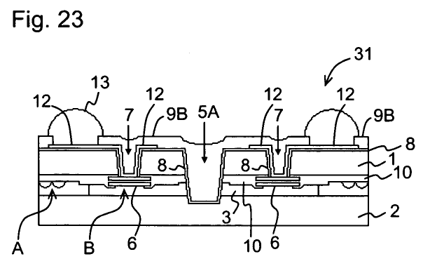

FIG. 23 is an essential part longitudinal cross sectional view schematically illustrating a cross sectional structure of the vicinity of a through hole electrode and a dicing area of an electronic element wafer module according to Embodiment 12 of the present invention.

As illustrated in FIG. 23, an electronic element wafer module 31 according to Embodiment 12 includes: an electronic element wafer 1; and a glass substrate 2, functioning as a support substrate, the electronic element wafer 1 and glass substrate 2 being laminated to each other by an adhesive resin layer 3. A groove 5A is formed, which penetrates the electronic element wafer 1 from the back surface side along a groove 5A of a dicing area 4 of the electronic element wafer 1 and reaches the front surface of the glass substrate 2 functioning as the support substrate on the front surface side. The groove 5A is formed simultaneously with a through hole 7 for connecting with an electrode pad 6 formed in a periphery section B of an electronic element area A at the center portion of each chip of the electronic element wafer 1. The side wall of the groove 5A is covered by an insulation film 8 on the back surface side of the electronic element wafer 1. The bottom surface of the groove 5A (bottom surface of the groove of the glass substrate 2) is also covered by the insulation film 8. A protection film 9B in the dicing area 4 buries not only the through hole 7 but also the groove 5. This point is what is different from Embodiment 4 described above.

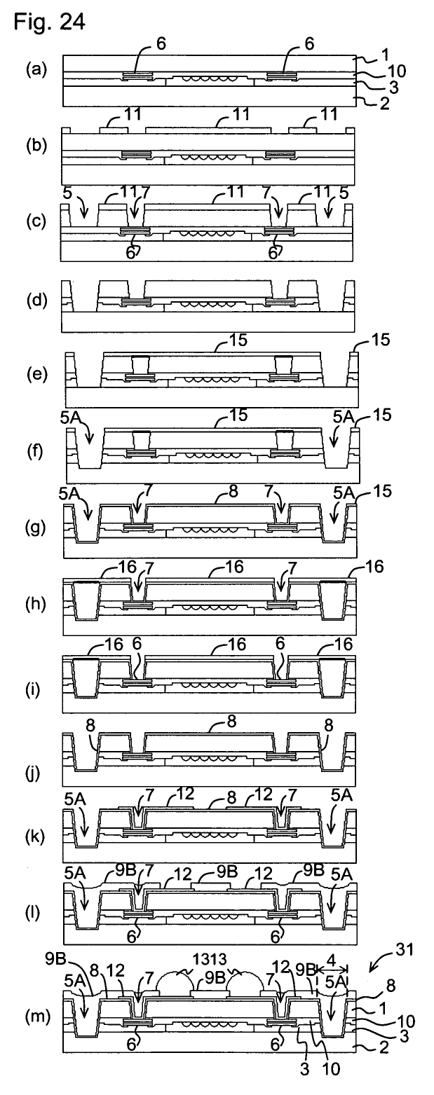

A method for manufacturing the electronic element wafer module 31 according to Embodiment 12 will be described in detail with reference to FIGS. 24(a) to 24(m).

FIGS. 24(a) to 24(m) are each an essential part longitudinal cross sectional view schematically illustrating a cross sectional structure of the vicinity of an electrode section and a dicing area in each of the processes for manufacturing the electronic element wafer module 31 according to Embodiment 12.

Prior to reaching the cross sectional structure of FIG. 24(a), a metal wiring layer (not shown) including the electrode pad 6 is formed on the surface of the electronic element wafer 1 through the first half of the processes of forming the semiconductor area, and an insulation film 10 is formed, which is opened above the center portion of the electrode pad 6.

FIG. 24(a) through FIG. 24(i), which illustrate subsequent processes, are the same as the cases in FIG. 8(a) through FIG. 8(i) of Embodiment 4 described above. Therefore, the description for each of the processes thereof will be omitted.

Next, as illustrated in FIG. 24(1), the protection film 9B is formed on the back surface side of the electronic element wafer 1. The method for forming the protection film 9B is not specifically limited, but any publicly known method can be used as appropriate. For example, the burying of the protection film 9B is possible into the through hole 7 and the dicing line groove 5A, by application, deforming in a vacuum, vacuum laminator, or a printing method (vacuum).

Further, as illustrated in FIG. 24(m), a solder bump 13 is formed thereon.

Subsequently, the electronic element wafer 1 is diced along the dicing line groove 5A to be individually separated into semiconductor chips. In Embodiment 12, the dicing line groove 5A is buried by the protection film 9B. Therefore, the package side wall surface and bottom surface subsequent to the individualization by dicing are covered by both the insulation film 8 and the thick protection film 9B. Further, the bottom surface of the dicing line groove 5A is located in the glass substrate 2 as a support substrate. Therefore, compared to the case of Embodiment 11 described above, the covering of the insulation film 8 is better, thereby completing a semiconductor apparatus with high reliability, and in particular, with high moisture-resistance.

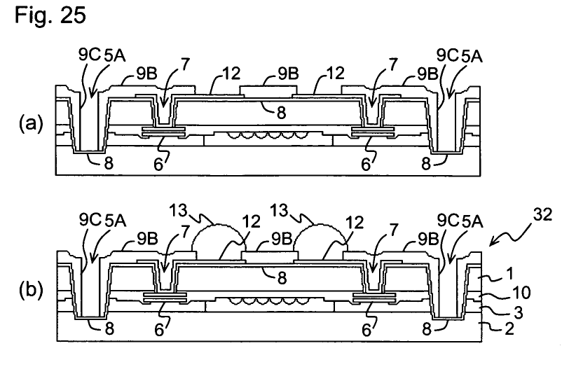

Further, as illustrated in FIG. 25, it is also possible to expose and develop the protection film 9B, which is covered or buried in the dicing line groove 5A, by photolithography to form an opening 9C, prior to the dicing of the electronic element wafer 1 and subsequent to the process of FIG. 24(m) in Embodiment 12 described above. According to this method, it becomes possible to avoid the shock during the dicing of the protection film 9B and to maintain the adhesion between the protection film 9B and the insulation film 8 of the side wall of the dicing line groove 5A. The same can be applied to Embodiments 9 to 11 described above, where the protection film 9B is buried in the dicing line groove 5 or 5A. Further, the same can be applied to Embodiments 5 to 8, where the dicing line groove 5 or 5A is covered by the protection film 9A.

The present invention is not limited to each of Embodiments 1 to 12 described above. Various variations are possible within the scope of the claims. Further, the technical scope of the present invention is included in an embodiment that can be obtained by appropriately combining the technical methods disclosed in different Embodiments 1 to 12.

Further, an optical element module may be laminated on the transparent glass substrate 2, the optical element module including a lens module as one or more lens plates.

That is, as an electronic element module, what is included is an electronic element chip (unit chip cut off of an electronic element wafer module) in which an image capturing element is provided as an electronic element; an adhesive resin layer 3 formed in a predetermined area on the electronic element chip; and one or more optical elements (e.g., lens plates) fixed on the adhesive resin layer 3 in such a manner to correspond to the image capturing element as an electronic element.

In the case described above, the electronic element may be an image capturing element including a plurality of light receiving sections for performing a photoelectric conversion on and capturing an image light from a subject; a light emitting element for generating an output light; or a light receiving element for receiving an incident light.

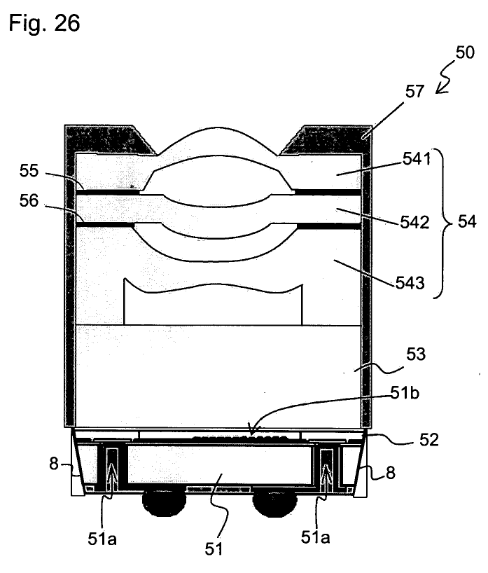

Embodiment 13 of the electronic element module will be described in detail with regard to an example of a sensor module with reference to FIG. 26. The sensor module as an electronic element module includes an image capturing element and a lens module, which are laminated therein, the image capturing element including a plurality of light receiving sections for performing a photoelectric conversion on and capturing an image light from a subject, and the lens module including one or more lenses for focusing an image of an incident light on the image capturing element.

### Embodiment 13

FIG. 26 is a longitudinal cross sectional view illustrating an exemplary essential structure of a sensor module according to Embodiment 13 of the present invention.

In FIG. 26, a sensor module 50 according to Embodiment 13 includes an image capturing element 51b as an electronic element constituted of a plurality of light receiving sections, which are photoelectric conversion sections (photodiodes) corresponding to a plurality of pixels, provided on a chip surface thereof. The sensor module 50 further includes: a through hole wafer 51 (corresponding to each chip individually separated from the electronic element wafer module according to Embodiments 1 to 12 described above) in which a through hole 51a is provided between the front surface and the back surface to electrically connect them as a wiring; a resin adhesive layer 52 (corresponding to the adhesive resin 3 according to Embodiments 1 to 12 described above) formed around the image capturing element 51b of the through hole wafer 51; a glass plate 53 (corresponding to the transparent glass substrate 2 as a support substrate according to Embodiments 1 to 12 described above) covering the resin adhesive layer 52 and individually separated as a cover glass on the surface of which an IR cut layer is coated; a lens plate 54 (lens module), in which a plurality of lens plates 541 to 543 are laminated as an optical element for focusing an incident light onto the image capturing element 51b, the lens plate 54 being provided on the glass plate 53; lens adhesive layers 55 and 56 for adhering and fixing the lens plates 541 to 543; and a light shielding member 57 for opening the middle portion of the lens plate 541, which is at the upper most position among the lens plates 541 to 543, as a light receiving opening of a round shape as well as for shielding the rest of the surface portions and the side surface portions of the lens plates 541 to 543 and glass plate 53. The glass plate 53 and the lens plate 54 are aligned in this order and adhered on top of another by the resin adhesive layer 52 and the lens adhesive layers 55 and 56, above the through hole wafer 51. In short, the sensor module 50 as an electronic element module according to Embodiment 13 is formed in such a manner that a plurality of lens plates 541 to 543 are adhered to each other by the lens adhesive layers 55 and 56 and the like on an individual piece cut off from the electronic element wafer module according to Embodiments 1 to 12 and the light shielding member 57 is further attached from above. As a result, the sensor module 50 according to Embodiment 13 is manufactured.

The lens plate 54 is made of a transparent resin or a transparent glass. The lens plate 54 is formed with a lens area having a lens function; and a peripheral flange as a spacer having a spacer function. The entire lens plate configuration is formed with the same type of a glass or resin material. With the structure described above, it is possible to form the lens plates 541 to 543 having a predetermined lens thickness.

In Embodiment 13, the lens plate 54 has a structure where three of the formed lens plates 541 to 543 are laminated at the lens flanges. The adhesive members 55 and 56 are used for the lamination, and the adhesive members 55 and 56 may have a light shielding function.

The lens plates 54 of a plurality of lenses as an optical element includes an aberration correcting lens 543, a diffusion lens 542, and a light focusing lens 541 (for a case with only one lens, the lens is a light focusing lens). In the lens plate 54, a lens area is provided at the middle portion and a lens flange is provided in the outer circumference side of the lens area, the lens flange having a predetermined thickness and functioning as a spacer section. Such lenses, or spacer sections, are provided on the outer circumference side of the lens plate 54, with a predetermined thickness. Each of the spacer sections is positioned from the bottom in this order. The spacer sections have a position determining function, and the position determining function is comprised of tapered convex and concave sections or alignment marks. The adhesive layers 55 and/or 56, which adhere the three lens plates 541 to 543, may also have a light shielding function, and the adhesive layers 55 and 56 may include a solid matter for determining a space.

Next, with a finished product using the sensor module 50 as the electronic element module as Embodiment 14, an electronic information device having the sensor module 50 according to Embodiment 13 used in an image capturing section will be described in detail with reference to the accompanying figures.

### Embodiment 14

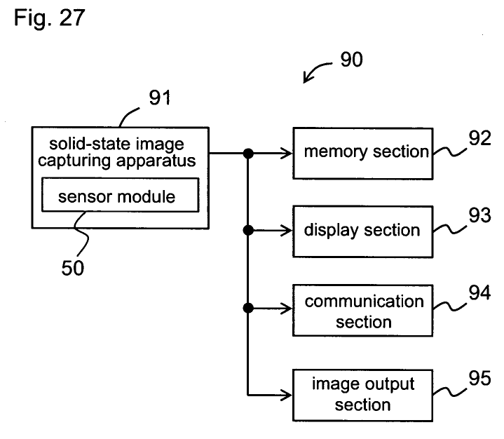

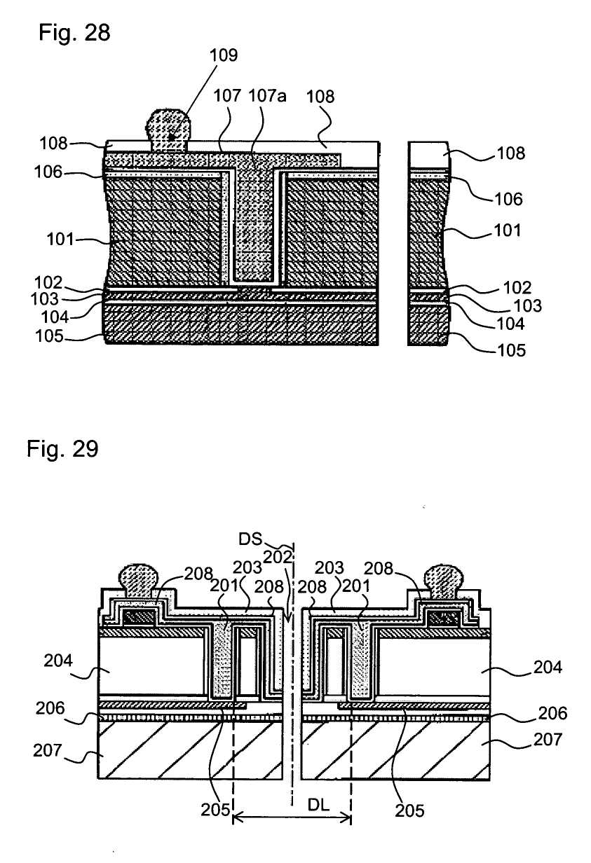

FIG. 27 is a block diagram illustrating an exemplary diagrammatic structure of an electronic information device of Embodiment 14 of the present invention, including the sensor module 50 according to Embodiment 13 of the present invention used in an image capturing section.

In FIG. 27, an electronic information device 90 according to Embodiment 14 of the present invention includes: a solid-state image capturing apparatus 91 for performing various signal processing on an image capturing signal from the sensor module 50 according to Embodiment 13 so as to obtain a color image signal; a memory section 92 (e.g., recording media) for data-recording a color image signal from the solid-state image capturing apparatus 91 after a predetermined signal process is performed on the color image signal for recording; a display section 93 (e.g., a liquid crystal display apparatus) for displaying the color image signal from the solid-state image capturing apparatus 91 on a display screen (e.g., liquid crystal display screen) after predetermined signal processing is performed on the color image signal for display; a communication section 94 (e.g., a transmitting and receiving device) for communicating the color image signal from the solid-state image capturing apparatus 91 after predetermined signal processing is performed on the color image signal for communication; and an image output section 95 (e.g., a printer) for printing the color image signal from the solid-state image capturing apparatus 91 after predetermined signal processing is performed for printing. Without any limitations to this, the electronic information device 90 may include, in addition to the solid-state image capturing apparatus 91, any of the memory section 92, the display section 93, the communication section 94, and the image output section 95.

As the electronic information device 90, an electronic information device that includes an image input device is conceivable, such as a digital camera (e.g., digital video camera and digital still camera), an image input camera (e.g., a monitoring camera, a door phone camera, a camera equipped in a vehicle, and a television camera), a scanner, a facsimile machine, a camera-equipped cell phone device, and a personal digital assistant (PDA).

Therefore, according to Embodiment 14 of the present invention, the color image signal from the solid-state image capturing apparatus 91 can be: displayed on a display screen finely by the display section 93, printed out on a sheet of paper using an image output section 95, communicated finely as communication data via a wire or a radio by the communication section 94, stored finely at the memory section 92 by performing predetermined data compression processing; and various data processes can be finely performed.

Without the limitation to the electronic information device 90 according to Embodiment 14 described above, the electronic information device may be a pick up apparatus having the electronic element module according to the present invention used in an information recording and reproducing section. The optical element of the pick up apparatus in this case is an optical function element (wafer-state optical apparatus: e.g., prism module and a hologram element module, or namely, a hologram optical element and a prism optical element) for advancing an output light straight to be outputted and for refracting an incident light to allow it to enter in a predetermined direction. In addition, the electronic element of the pick up apparatus includes a light emitting element for generating an output light (e.g., semiconductor laser element or a laser chip) and a light receiving element for receiving an incident light (e.g., photo IC).

As described above, the present invention is exemplified by the use of its preferred Embodiments 1 to 14. However, the present invention should not be interpreted solely based on Embodiments 1 to 14 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 14 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of an electronic element wafer module, in which a surface of an electronic element wafer provided with a plurality of electronic elements, and a support substrate are laminated to each other; a method for manufacturing the electronic element wafer module; an electronic element module in which each individual piece is made by cutting off the electronic element wafer module for each electronic element; and an electronic information device, such as a digital camera (e.g., a digital video camera and a digital still camera), an image input camera, a scanner, a facsimile machine, and a camera-equipped cell phone device, having the electronic element module as an image input device used in an image capturing section thereof. The present invention provides a through hole electrode that has high reliability, and in particular, high moisture-resistance.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. An electronic element wafer module, comprising:
electronic element wafers, in which a plurality of electronic elements are provided on a front surface side and wiring is provided on a back surface side, the wiring being electrically connected to wiring or a terminal section on the front surface side through a through hole penetrating through both surfaces; and
support substrates adhered by a resin adhesive layer, opposing the front surface side of the electronic element wafer,
wherein: a groove for dicing is formed along a dicing line in between adjacent electronic elements, penetrating the electronic element wafers from the back surface; and
an insulation film for insulating a semiconductor layer from the wiring on the back surface is formed on the back surface of the electronic element wafer including the through hole and is formed at least on a side wall of the groove.

2. An electronic element wafer module according to claim 1, wherein an electrode pad is provided as the wiring or terminal section in a periphery of the electronic element, and the electrode pad is connected to the wiring on the back surface through the through hole.

3. An electronic element wafer module according to claim 1, wherein the insulation film insulates an electric connection layer in the through hole and an inner wall of the through hole, the through hole being for electrically connecting the electrode pad provided in a periphery of the electronic element and the wiring or an external connection terminal.

4. An electronic element wafer module according to claim 1, wherein a back surface protection film is provided at least on the through hole on the back surface and the wiring.

5. An electronic element wafer module according to claim 1, wherein a bottom surface of the groove is either covered by the insulation film or removed.

6. An electronic element wafer module according to claim 5, wherein the bottom surface of the groove is located either on the support substrate or in the support substrate.

7. An electronic element wafer module according to claim 4, wherein the back surface protection film covers at least the side wall of the side wall and bottom surface of the groove.

8. An electronic element wafer module according to claim 4, wherein the back surface protection film is buried inside the groove.

9. An electronic element wafer module according to claim 1, wherein the support substrate is a transparent resin substrate or a transparent glass substrate as a transparent member.

10. An electronic element wafer module according to claim 1, wherein the insulation film is a photosensitive resin film, a Si oxide film, a boron or phosphor containing oxide film, Si oxynitride film, Si nitride film, or a laminated layer comprised of at least two types thereof, or a film formed with electrodeposition material.

11. An electronic element wafer module according to claim 10, wherein the photosensitive resin film is a polyimide resin, an epoxy resin or a acrylic resin.

12. An electronic element wafer module according to claim 10, wherein the electrodeposition material is a polyimide resin, an epoxy resin, a acrylic resin, a polyamine resin, or a polycarboxylic acid resin.

13. An electronic element wafer module according to claim 1, wherein an insulation film is further provided to insulate the wiring or terminal section from the semiconductor layer on the front surface of the electronic element wafer, and the insulation film is a Si oxide film, a boron or phosphor containing oxide film, Si oxynitride film, Si nitride film, or a laminated layer comprised of at least two types thereof.

14. An electronic element wafer module according to claim 4, wherein the back surface protection film is formed of a photosensitive resin film.

15. An electronic element wafer module according to claim 14, wherein the photosensitive resin film is a polyimide resin, an epoxy resin, a acrylic resin, a silicone resin, or a mixed resin comprised of at least two types thereof.

16. An electronic element wafer module according to claim 1, wherein the electronic element is an image capturing element including a plurality of light receiving sections for performing a photoelectric conversion on and capturing an image light from a subject.

17. An electronic element wafer module according to claim 1, wherein the electronic element includes a light emitting element for generating an output light and a light receiving element for receiving an incident light.

18. An electronic element wafer module according to claim 9, further including one or a plurality of laminated wafer-state optical apparatuses adhered and fixed on the transparent member in such a manner to correspond to each of the plurality of electronic elements.

19. An electronic element wafer module according to claim 18, wherein the one or a plurality of laminated wafer-state optical apparatuses are lens modules, and the electronic elements are image capturing elements.

20. An electronic element wafer module according to claim 18, wherein the one or a plurality of laminated wafer-state optical apparatuses are either prism modules or hologram element modules, and the electronic elements are light emitting elements and light receiving elements.

21. A method for manufacturing an electronic element wafer module, comprising:
a step of laminating a support substrate opposing a front surface side of an electronic element wafer by a resin adhesive layer, the electronic element wafer having a plurality of electronic elements formed thereon;
a through hole and groove forming step of forming a through hole, which penetrates through both surfaces of the electronic element wafer, for each electronic element and forming a groove for dicing, which penetrates the electronic element wafer from a back surface along a dicing line in between adjacent electronic elements;
an insulation film forming step of forming an insulation film on the back surface of the electronic element wafer including the through hole and the groove; and
a wiring layer forming step of forming a wiring layer on the insulation film, the wiring layer electrically connecting with wiring or a terminal section on the front surface side of the electronic element wafer through the through hole.

22. A method for manufacturing an electronic element wafer module according to claim 21, further including a back surface protection film forming step of forming a back surface protection film on at least the wiring layer and the through hole.

23. A method for manufacturing an electronic element wafer module according to claim 21, further including an insulation film removing step of removing an insulation film on a bottom surface of the groove subsequent to the insulation film forming step.

24. A method for manufacturing an electronic element wafer module according to claim 21, wherein the through hole and groove forming step forms the groove such that a bottom surface of the groove is located on the support substrate or in the support substrate.

25. A method for manufacturing an electronic element wafer module according to claim 22, wherein the back surface protection film forming step buries the through hole with the back surface protection film and forms the back surface protection film on the groove or on an area other than the groove.

26. A method for manufacturing an electronic element wafer module according to claim 22, wherein the back surface protection film forming step forms the back surface protection film in such a manner to bury the through hole and the groove.

27. An electronic element module individually separated by cutting off every one or a predetermined number from the electronic element wafer module according to claim 1.

28. An electronic information device including the electronic element module, which is cut off from the electronic element wafer module according to claim 19, as a sensor module in an image capturing section.

29. An electronic information device including the electronic element module, which is cut off from the electronic element wafer module according to claim 20, in an information recording and reproducing section.
